(19) United States
(12) Patent Application Publication
(10) Pub. No.: US 2025/0218981 A1
(43) Pub. Date: Jul. 3, 2025

(54) SEMICONDUCTOR DEVICE

(71) Applicant: Samsung Electronics Co., Ltd., Suwon-si (KR)

(72) Inventors: Donghwan Lee, Suwon-si (KR); Wonchul Lee, Suwon-si (KR)

(21) Appl. No.: 18/779,133

(22) Filed: Jul. 22, 2024

(30) Foreign Application Priority Data
Dec. 27, 2023 (KR) 10-2023-0193177

(51) Int. Cl. H01L 23/60

(52) U.S. Cl. CPC H01L 23/60

(57) ABSTRACT

A semiconductor device includes a substrate having a first region and a second region, an integrated circuit structure in the first region, a guard ring surrounding the integrated circuit structure in the second region, a plurality of vias arranged on the guard ring, and a conductive line arranged on the plurality of vias. The integrated circuit structure includes a circuit active fin in the first region, a gate structure intersecting the circuit active fin, a source/drain region on an active fin adjacent to a side surface of the gate structure, a circuit contact structure on the source/drain region, and a circuit wiring structure on the circuit contact structure. The guard ring includes a guard active structure in the second region, a plurality of guard contact structures arranged on the guard active structure, and a guard wiring structure on the guard contact structures.

### CROSS-REFERENCE TO RELATED APPLICATION

This application is based on and claims priority under 35 U.S.C. § 119 to Korean Patent Application No. 10-2023-0193177, filed on Dec. 27, 2023, in the Korean Intellectual Property Office, the disclosure of which is incorporated by reference herein in its entirety.

### BACKGROUND

The inventive concept relates to a semiconductor device, and more particularly, to a semiconductor device including a guard ring.

Recently, as demand for high performance, high speed, and/or multi-functionality for semiconductor devices increases, a degree of integration of semiconductor devices is increasing. In manufacturing a fine-patterned semiconductor device in response to a trend of high integration of semiconductor devices, it is required to implement patterns with fine widths or fine spacing. In addition, in order to overcome limitations in operating characteristics due to size reduction of planar metal oxide semiconductor field effect transistors (MOSFETs), efforts are being made to develop semiconductor devices including FinFETs with three-dimensional channels.

### SUMMARY

Aspects of the inventive concept relate to a semiconductor device with improved reliability.

The problems to be solved by the technical idea of the inventive concept are not limited to the above-mentioned problems, and other problems not mentioned will be clearly understood by those skilled in the art from the following description.

According to an aspect of the inventive concept, there is provided a semiconductor device including a substrate having a first region and a second region surrounding the first region, an integrated circuit structure on the substrate in the first region, a guard ring surrounding the integrated circuit structure on the substrate in the second region, a plurality of vias arranged on the guard ring, and a conductive line arranged on the plurality of vias. The integrated circuit structure includes a circuit active fin on the substrate in the first region, a gate structure intersecting the circuit active fin, a source/drain region on an active fin adjacent to a side surface of the gate structure, a circuit contact structure on the source/drain region, and a circuit wiring structure on the circuit contact structure. The guard ring includes a guard active structure on the substrate in the second region, a plurality of guard contact structures arranged on the guard active structure, and a guard wiring structure on the guard contact structures. The guard contact structures overlap the plurality of vias in a vertical direction perpendicular to a top surface of the substrate.

According to another aspect of the inventive concept, there is provided a semiconductor device including a substrate, an integrated circuit structure arranged on the substrate, a guard ring arranged on the substrate to surround the integrated circuit structure at a position adjacent to an edge of the substrate, a plurality of vias arranged on the guard ring, and a conductive line connected to the plurality of vias. The integrated circuit structure includes a circuit active fin on the substrate, a gate structure intersecting the circuit active fin, a source/drain region on a circuit active fin adjacent to a side surface of the gate structure, a circuit contact structure on the source/drain region, and a circuit wiring structure on the circuit contact structure. The guard ring includes a guard active structure on the substrate, a plurality of guard contact structures arranged on the guard active structure, and a guard wiring structure on the guard contact structures. The plurality of vias are arranged at positions that do not overlap the guard contact structures in a vertical direction.

According to another aspect of the inventive concept, there is provided a semiconductor device including an integrated circuit structure on a substrate, a guard ring surrounding the integrated circuit structure on the substrate, a conductive line at a vertical level higher than the guard ring, a plurality of vias between a guard wiring structure and the conductive line, and an insulating material structure on a side surface of the guard ring. The integrated circuit structure includes a circuit active fin on the substrate, a gate structure intersecting the circuit active fin, a source/drain region on a circuit active fin adjacent to a side surface of the gate structure, a circuit contact structure on the source/drain region, and a circuit wiring structure on the circuit contact structure. The guard ring includes a guard active structure on the substrate, guard contact structures arranged on the guard active structure to be apart from one another, and the guard wiring structure on the guard contact structures. The source/drain region is between the circuit contact structure and the circuit active fin. A width of a top surface of each of the guard contact structures is equal to or less than a width of a top surface of the circuit contact structure. A bottom surface of the guard wiring structure contacts a topmost surface of each of the guard contact structures. A topmost surface of the guard wiring structure contacts bottom surfaces of the plurality of vias.

### BRIEF DESCRIPTION OF THE DRAWINGS

Embodiments will be more clearly understood from the following detailed description taken in conjunction with the accompanying drawings in which:

FIG. 1 is a plan view illustrating a semiconductor device according to embodiments;

FIG. 2 is a partially enlarged view of a guard ring region of a semiconductor device according to embodiments;

FIG. 3 is a cross-sectional view illustrating a guard ring region of a semiconductor device according to embodiments;

FIG. 4 is a cross-sectional view illustrating a guard ring region of a semiconductor device according to embodiments;

FIG. 5 is a cross-sectional view illustrating a guard ring region of a semiconductor device according to embodiments;

FIG. 6 is a cross-sectional view illustrating a guard ring region of a semiconductor device according to embodiments;

FIG. 7 is a cross-sectional view illustrating a guard ring region of a semiconductor device according to embodiments;

FIG. 8 is a partially enlarged view of a semiconductor device according to embodiments;

FIGS. 9A to 9D are cross-sectional views illustrating a semiconductor device according to embodiments; and

FIGS. 10A to 16C are views illustrating a method of manufacturing a semiconductor device according to embodiments in a process order.

### DETAILED DESCRIPTION OF THE EMBODIMENTS

Hereinafter, embodiments of the inventive concept will be described in detail with reference to the accompanying drawings. Like reference numerals refer to like elements, and their repetitive descriptions are omitted.

Because the current embodiments may be modified in various ways and have various embodiments, specific embodiments will be illustrated in the drawings and described in detail in the detailed description. However, this is not intended to limit the scope to specific embodiments, and should be understood to include all transformations, equivalents, and substitutes included in the disclosed spirit and technical scope.

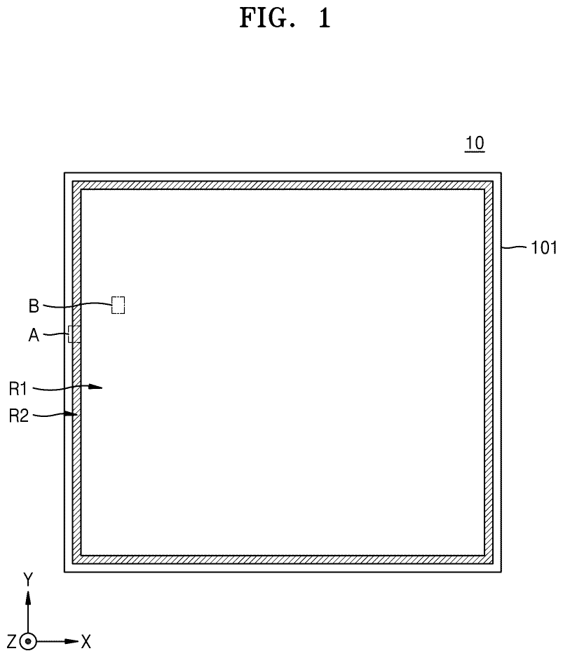

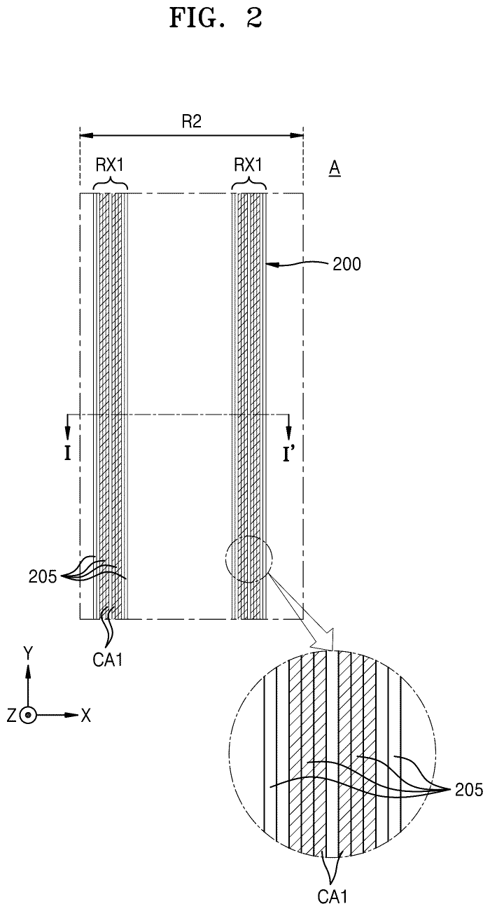

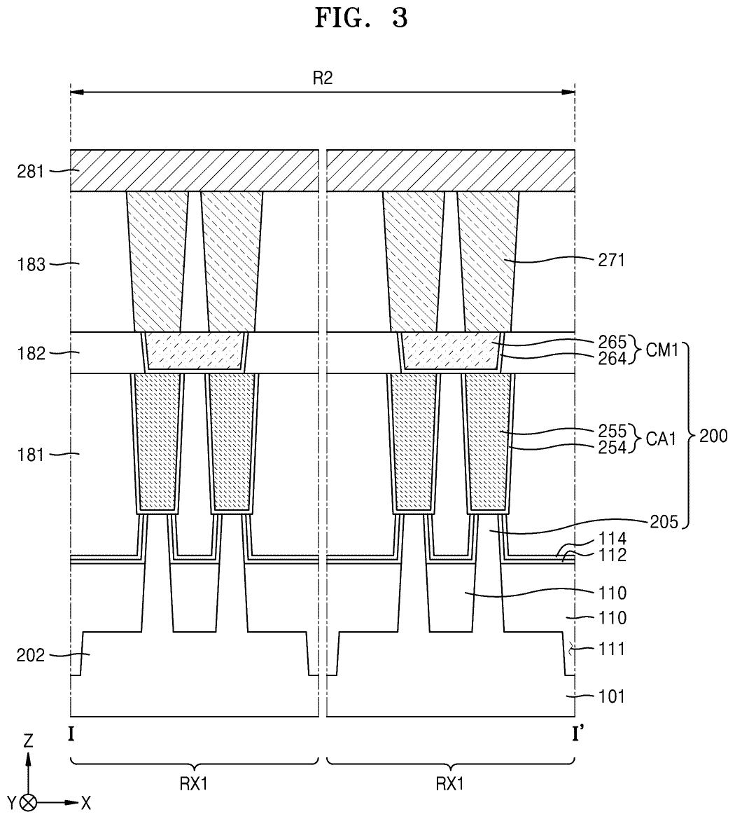

First, a semiconductor device according to an embodiment will be described with reference to FIGS. 1 to 3. FIG. 1 is a plan view illustrating a semiconductor device 10 according to embodiments, FIG. 2 is a partially enlarged view of a region ‘A’ of FIG. 1, and FIG. 3 is a cross-sectional view taken along the line I-I′ of FIG. 2.

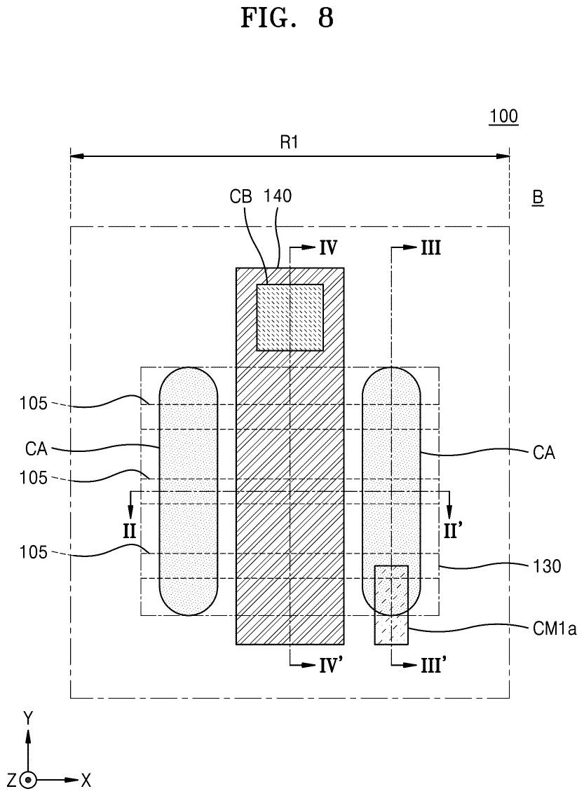

Referring to FIGS. 1 to 3, the semiconductor device 10 may include a substrate 101 having a first region R1 and a second region R2, an integrated circuit structure 100 (refer to FIG. 8) on the substrate 101 in the first region R1, and a guard ring 200 on the substrate 101 in the second region R2. The first region R1 may be a central region of the substrate 101 and the second region R2 may surround the first region R1. The semiconductor device 10 may include insulating material structures 110, 112, 114, 181, 182, 183, and 184 on side surfaces of the guard ring 200. The insulating material structures 110, 112, 114, 181, 182, 183, and 184 may include a device isolation region 110, first and second protective layers 112 and 114, and first to fourth interlayer insulating layers 181, 182, 183, and 184.

The substrate 101 may include or be formed of a semiconductor material, for example, a group IV semiconductor, a group III-V compound semiconductor, or a group II-VI compound semiconductor. For example, the group IV semiconductor may include or may be silicon (Si), germanium (Ge), or silicon germanium (SiGe). The substrate 101 may be provided as a bulk wafer, silicon on insulator (SOI) layer, or a semiconductor on insulator (SEOI) layer.

The guard ring 200 is exemplarily illustrated in the drawing to have a square shape, but is not limited thereto, and may have any shape as long as it surrounds the integrated circuit structure 100 in the first region R1. A plurality of guard rings 200 may be formed, and the plurality of guard rings 200 may be arranged side by side in an outward direction from the center of the first region R1. However, the inventive concept is not limited thereto, and the guard ring 200 may have a repetitive pattern and may be arranged to surround the first region R1. The guard ring 200 may be adjacent to an edge of the substrate 101.

The guard ring 200 may include guard active fins 205 extending in the second region R2 to surround the first region R1, guard contact structures CA1 on the guard active fins 205, and guard wiring structures CM1 on the guard contact structures CA1.

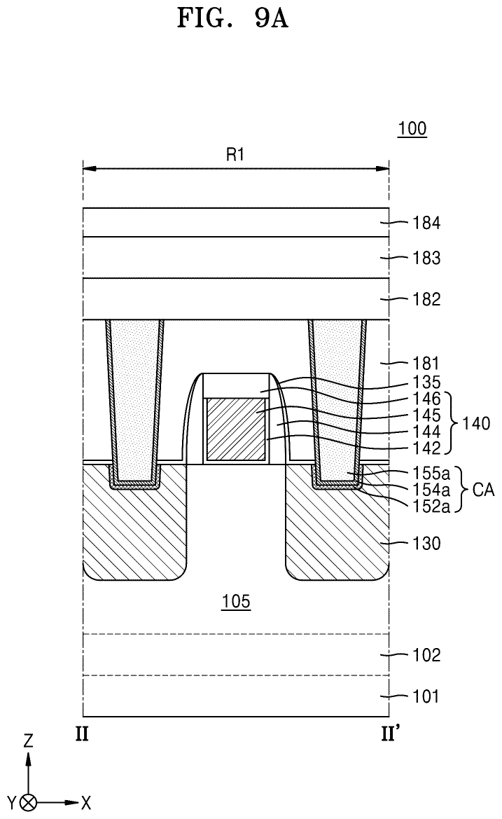

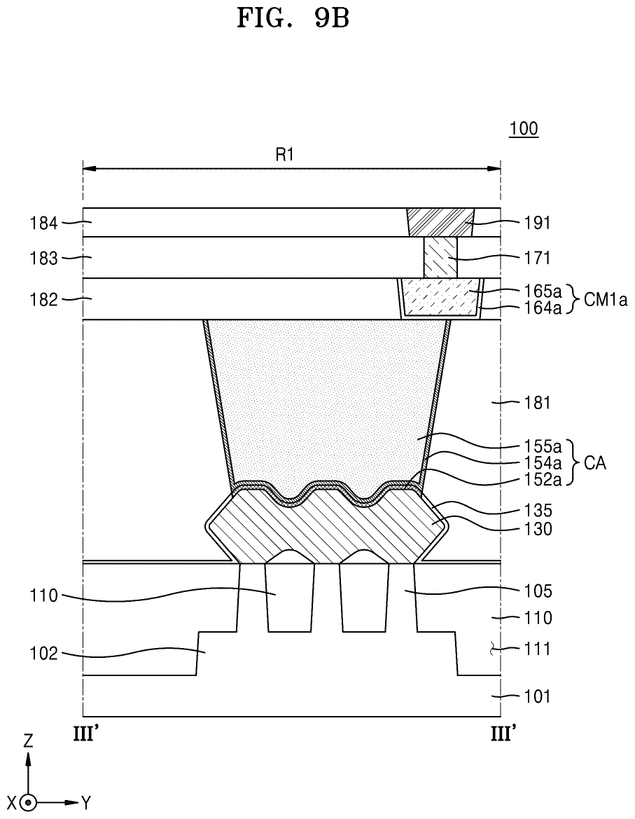

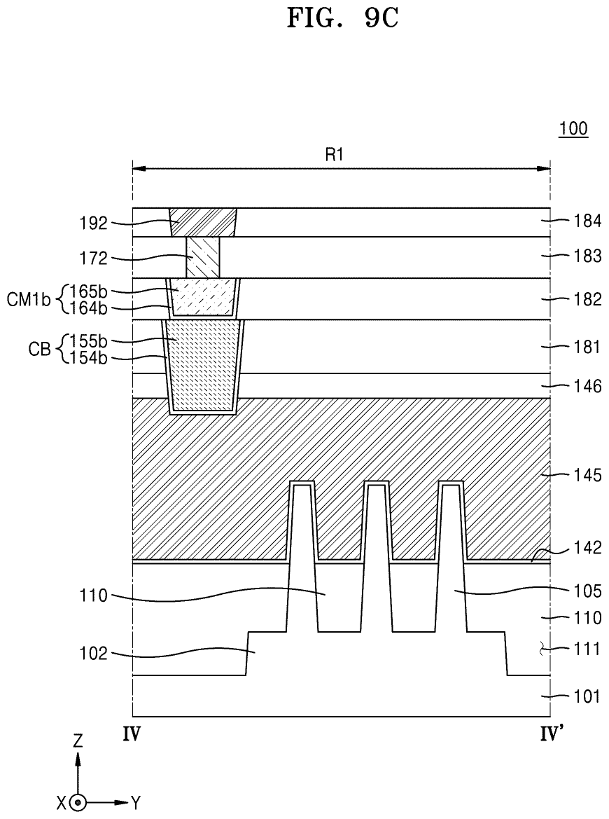

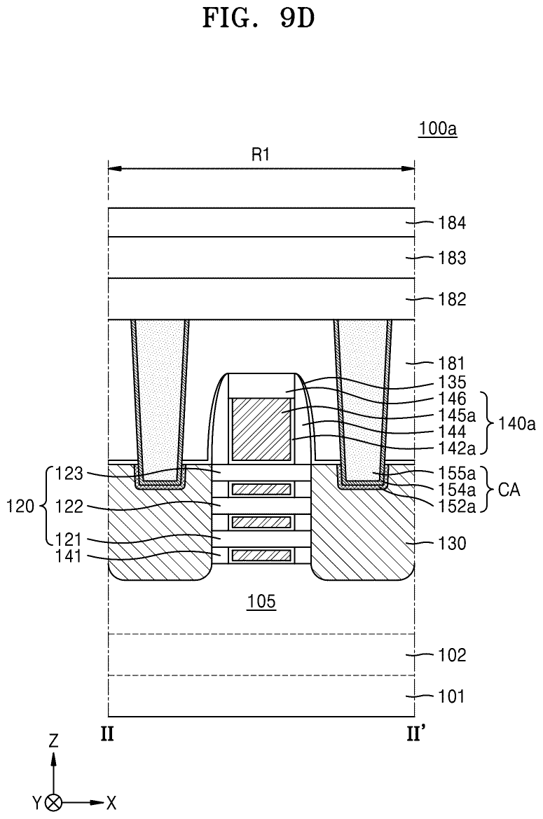

The guard active fins 205 may have a fin structure and may be defined by the device isolation region 110 within the substrate 101. The guard active fins 205 may protrude from the substrate 101. Upper ends of the guard active fins 205 may be arranged to protrude from a top surface of the device isolation region 110 at a predetermined height. The guard active fins 205 may be formed as a part of the substrate 101 or may include an epitaxial layer grown from the substrate 101. Each of the guard active fins 205 may have a width, a height, and a distance different from those of each of active fins 105 (refer to FIGS. 8 to 9D) of the integrated circuit structure 100 or may have the same width, height, and distance as those of each of the active fins 105. For example, each of the guard active fins 205 may have a width greater than that of each of the active fins 105 of the integrated circuit structure 100.

In a pair of guard active fins 205 adjacent to each other among the guard active fins 205, one may contact one of the guard contact structures CA1 and the other may not contact the guard contact structure CA1. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

The plurality of guard active fins 205 may be arranged side by side and may form a guard active structure RX1 together with a guard active region 202. A plurality of guard active structures RX1 may be arranged side by side.

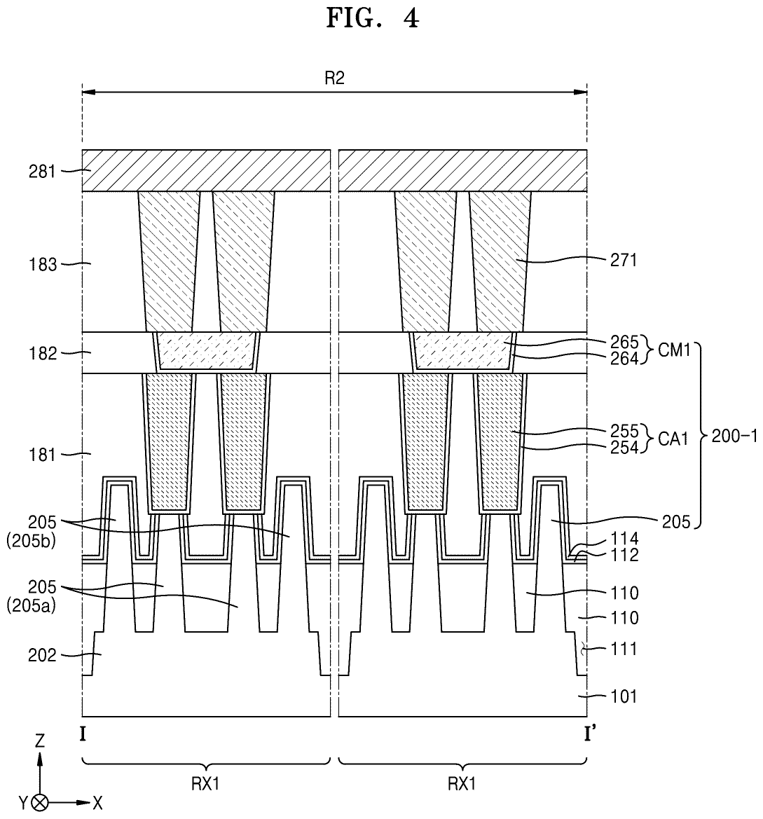

According to embodiments, the guard active structure RX1 may include one or a plurality of active fins, and the number, arrangement, width, and distance of the active fins are not limited to those illustrated in the drawing. Referring to FIG. 3, although it is illustrated that two guard active fins 205 are arranged per guard active structure RX1, three or more guard active fins may be arranged per guard active structure RX1 (refer to FIG. 4).

The device isolation region 110 may define the guard active fins 205 in the substrate 101. The device isolation region 110 may be formed by, for example, a shallow trench isolation (STI) process. The device isolation region 110 may expose upper sidewalls of the guard active fins 205. According to embodiments, the device isolation region 110 may include a deep device isolation region 111 extending deeper into a lower portion of the substrate 101 than other parts of the device isolation region 110 between the guard active fins 205. The device isolation region 110 may have a curved top surface at a higher level as the device isolation region 110 approaches the guard active fins 205, and a shape of the top surface of the device isolation region 110 is not limited thereto. The device isolation region 110 may include an insulating material. The device isolation region 110 may include, for example, oxide, nitride, or a combination thereof. Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

The plurality of guard contact structures CA1 may be respectively arranged/disposed on the guard active structures RX1. Each of the guard contact structures CA1 may pass through the first interlayer insulating layer 181 to contact each of the guard active fins 205. The guard contact structures CA1 may be apart from one another in an X direction to respectively contact the guard active fins 205. The guard contact structures CA1 may recess upper portions of the guard active fins 205 to contact the guard active fins 205. For example, the guard contact structures CA1 may be formed on the guard active fins 205 after removing a portion of the upper portion of the guard active fins 205. Lower ends of the guard contact structures CA1 may be arranged below the uppermost ends of the guard active fins 205. The guard contact structure CA1 may have an inclined side surface in which a width of a lower portion of the guard contact structure CA1 is less than a width of an upper portion of the guard contact structure CA1. For example, when a guard contact hole is formed in the first interlayer insulating layer 181, a lower part of the guard contact hole may have a width less than a width of an upper part of the guard contact hole according to an aspect ratio of the guard contact hole. However, the inventive concept is not limited thereto.

A height difference between lower and upper surfaces of the guard contact structure CA1 may be greater than a height difference between lower and upper surfaces of a circuit contact structure CA. The upper surface of the guard contact structure CA1 and the upper surface of the circuit contact structure CA may be at the same level.

The guard contact structures CA1 may be arranged to partially overlap the guard active fins 205 in a direction perpendicular to a top surface of the substrate 101. From a plan view, the guard contact structure CA1 may have a shape corresponding to the guard active fin 205. For example, when the guard active fins 205 have a line shape extending in one direction, for example, the Y direction, the guard contact structure CA1 may also have a line shape extending in the Y direction while overlapping at least parts of the guard active fins 205.

A pair of guard contact structures CA1 may formed one guard active structure RX1. For example, one guard active structure RX1 may include at least two active fins, and the pair of guard contact structures CA1 may be respectively connected to adjacent guard active fins 205. Each of the guard contact structures CA1 may contact one of a pair of guard active fins 205 adjacent to each other and may be apart from the other guard active fin 205.

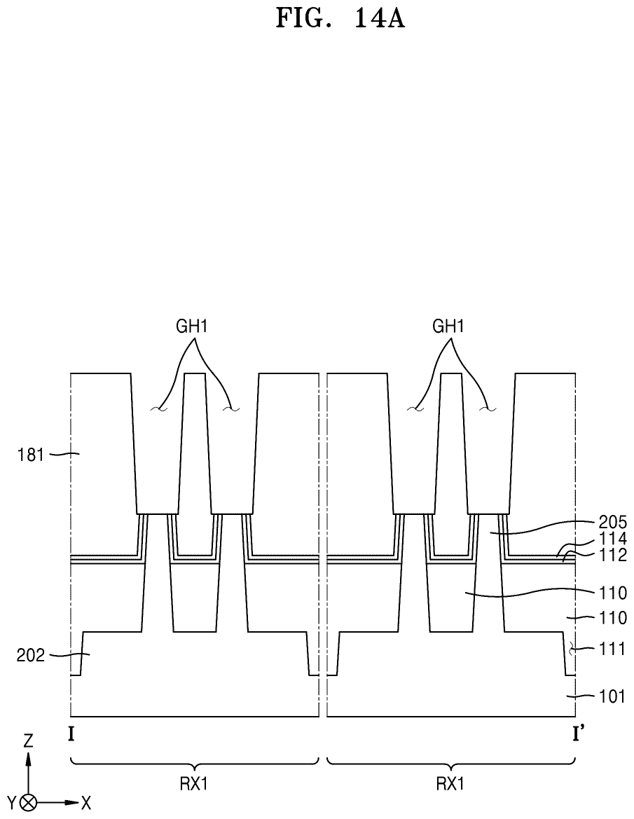

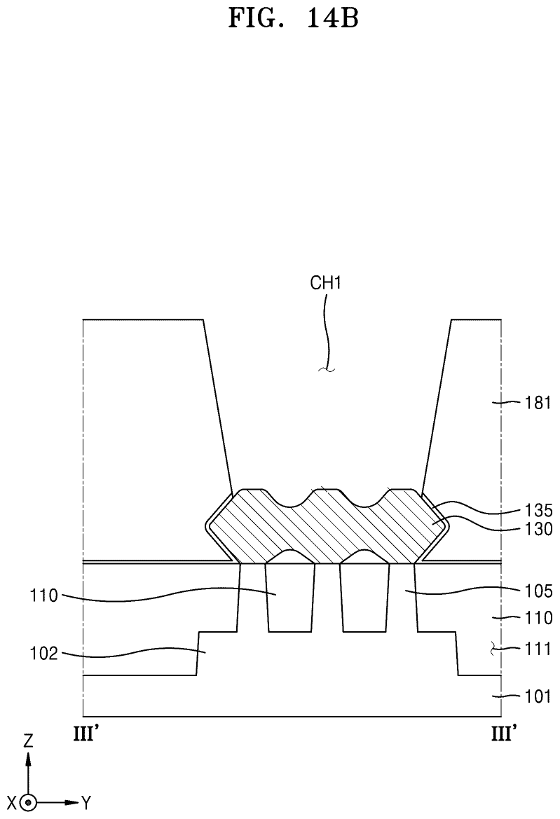

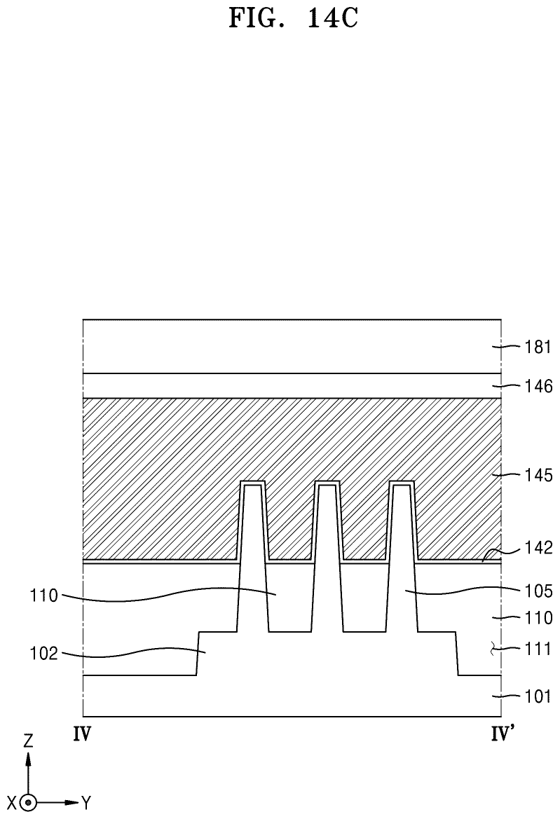

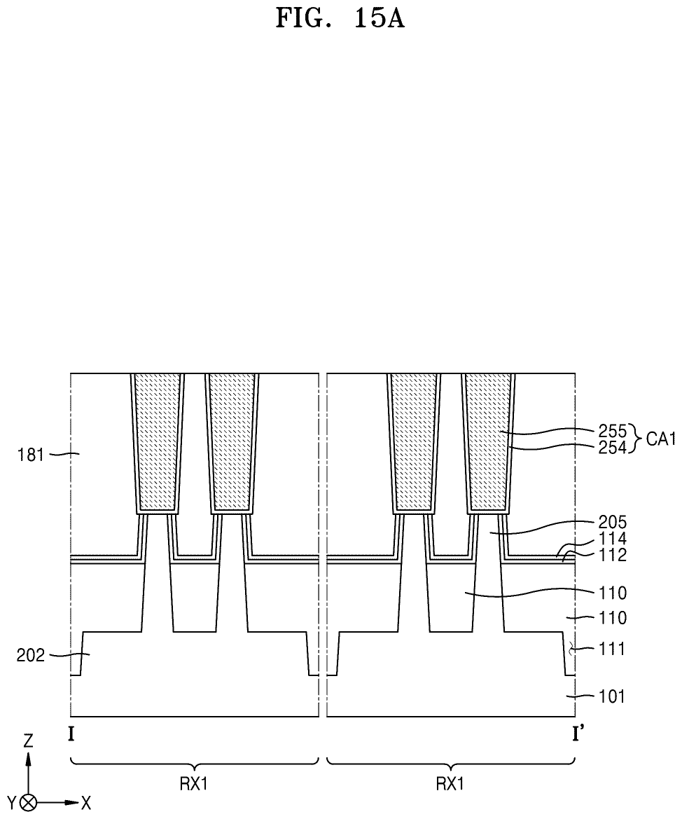

In embodiments, a width of an upper end of the guard contact structure CA1 in the X direction may be less than or equal to a width of the circuit contact structure CA (refer to FIGS. 8 to 9D) of the integrated circuit structure 100 in the X direction. When a pair of the guard contact structures CA1 are formed on one guard active fin structure RX1, a size of each guard contact hole GH1 (refer to FIG. 14A) for forming the guard contact structure CA1 may be reduced. For example, when a pair of guard contact hole GH1 is formed on one guard active fin structure RX1, a plan view area of each guard contact hole GH1 may be smaller than a plan view area of a guard contact hole in a case where only one guard contact hole GH1 is formed on one guard active fin structure RX1. A width of each of the guard contact structures CA1 in the X direction may be less than a width of each of circuit contact structures CA (refer to FIGS. 8 to 9D) in the X direction. However, the sum of widths of adjacent guard contact structures CA1 in the X direction may be greater than a width of each of the circuit contact structures CA (refer to FIGS. 8 to 9D) in the X direction. For example, a sum of X direction widths of a pair of guard contact structures CA1 formed on a guard active fin structure RX1 may be greater than an X direction width of each circuit contact structure CA.

The guard contact structure CA1 may include a guard barrier layer 254 and a guard contact plug 255. The guard barrier layer 254 may surround the guard contact plug 255. The guard barrier layer 254 may cover side and bottom surfaces of the guard contact plug 255. The guard barrier layer 254 may be arranged between the guard active fins 205 and the guard contact plug 255.

The guard barrier layer 254 may include a metal nitride layer such as a titanium nitride layer (TiN), a tantalum nitride layer (TaN), or a tungsten nitride layer (WN). The guard contact plug 255 may include, for example, tungsten (W), cobalt (Co), titanium (Ti), an alloy thereof, or a combination thereof.

The first and second protective layers 112 and 114 may be arranged on the side surfaces of the guard ring 200. The first and second protective layers 112 and 114 may conformally cover the guard active fins 205 and the device isolation region 110. The first protective layer 112 may cover the guard active fins 205 and the device isolation region 110 and the second protective layer 114 may cover the first protective layer 112. The first and second protective layers 112 and 114 may protect the guard active fins 205 in the second region R2 while manufacturing processes of the integrated circuit structure 100 are performed in the first region R1, e.g., while patterns are formed in the first region R1.

The guard contact structures CA1 may contact the first and second protective layers 112 and 114. At least parts of the first and second protective layers 112 and 114 may contact the lower ends of the guard contact structures CA1. The first interlayer insulating layer 181 may cover the first and second protective layers 112 and 114. The first and second protective layers 112 and 114 may cover top surfaces of the guard active fins 205 that do not contact the guard contact structures CA1 among the guard active fins 205.

The first and second protective layers 112 and 114 may include oxide, nitride, or oxynitride, and may specifically include at least one of SiO, SiN, SiCN, SiOC, SiON, and SiOCN. In an embodiment, the first protective layer 112 may include silicon oxide, and the second protective layer 114 may include silicon nitride. The second protective layer 114 may include the same material as that of an etch stop layer 135 (refer to FIG. 9D) of the integrated circuit structure 100.

In the current embodiment, a gate structure extending across the guard active fins 205 may not be arranged in the second region R2. For example, a gate structure 140 (refer to FIGS. 8 to 9D) may be arranged to extend across the active fins 105 only in the first region R1.

The guard wiring structure CM1 may pass through the second interlayer insulating layer 182 to electrically connect the pair of guard contact structures CA1 to each other. The guard wiring structure CM1 may have an inclined side surface in which a width of a lower portion of the guard wiring structure CM1 is less than a width of an upper portion of the guard wiring structure CM1. For example, when the second interlayer insulating layer 182 is patterned to form the guard wiring structure CM1 in the second interlayer insulating layer 182, an upper part of the second interlayer insulating layer 182 may be more widely etched than a lower part of the second interlayer insulating layer 182 according to an aspect ratio of the etching portion. However, the inventive concept is not limited thereto. The guard wiring structure CM1 may contact top surfaces of the pair of guard contact structures CA1. The guard wiring structure CM1 may overlap the insulating material structures 110, 112, 114, 181, 182, 183, and 184 positioned between the pair of guard contact structures CA1 in a plan view, and above the pair of guard contact structures CA1 in a Z direction.

The first interlayer insulating layer 181 may be arranged between the pair of guard contact structures CA1 under the guard wiring structure CM1. At least a part of a lower end of the guard wiring structure CM1 may contact a top surface of the first interlayer insulating layer 181.

Both opposing side surfaces of the guard wiring structure CM1 may overlap the top surfaces of the adjacent guard contact structures CA1 in a vertical direction. The center between the both opposing side surfaces of the guard wiring structure CM1 may overlap the insulating material structures 110, 112, 114, 181, 182, 183, and 184 in the vertical direction.

The guard wiring structure CM1 may include a conductive barrier layer 264 and a guard wiring layer 265. The conductive barrier layer 264 may surround the guard wiring layer 265. The conductive barrier layer 264 may surround/contact side and bottom surfaces of the guard wiring layer 265.

The conductive barrier layer 264 may include a metal nitride layer such as a titanium nitride layer (TiN), a tantalum nitride layer (TaN), or a tungsten nitride layer (WN). The guard wiring layer 265 may include, for example, W, Co, Ti, an alloy thereof, or a combination thereof.

In the current embodiment, vias 271 on the guard wiring structure CM1 of the guard ring 200 and a conductive line 281 on the vias 271 may be further arranged. The conductive line 281 may overlap the guard ring 200 and the insulating material structures 110, 112, 114, 181, 182, 183, and 184 in the vertical direction. The vias 271 may be electrically connected to, e.g., contact, the guard wiring structure CM1 below the conductive line 281. As used herein, components described as being “electrically connected” are configured such that an electrical signal can be transferred from one component to the other (although such electrical signal may be attenuated in strength as it is transferred and may be selectively transferred).

In FIG. 3, the vias 271 and the guard contact structures CA1 are illustrated as overlapping each other in the Z direction, which is only an exemplary illustration and the inventive concept is not limited thereto. In embodiments, a distance between the adjacent vias 271 may be different from a distance between the adjacent guard contact structures CA1. Because the number and arrangement of the vias 271 and the number and arrangement of the guard contact structures CA1 are independent from each other, as shown in embodiments described below, guard rings 200, 200-1, 200-2, 200-3, and 200-4 may be formed in various combinations.

The conductive line 281 and other upper wirings connected thereto may not be electrically connected to other upper wirings on the integrated circuit structure 100. Through the guard ring 200 including the guard active fins 205, the guard contact structures CA1, and the guard wiring structures CM1, the conductive line 281 and other upper wirings connected thereto may be grounded to the substrate 101. Accordingly, it is possible to minimize an electrostatic current that may flow into the integrated circuit structure 100 from the outside and to prevent the integrated circuit structure 100 from being damaged.

FIG. 4 is a cross-sectional view illustrating a guard ring 200-1 region of a semiconductor device 10 according to embodiments. Guard ring regions in the present disclosure respectively denote corresponding guard rings and their vicinities. FIG. 4 may be a cross-sectional view of another embodiment taken along the line I-I′ of FIG. 2. In FIG. 4, the same reference numerals as in FIG. 3 denote the same members, and redundant description thereof will be omitted. Because the cross-sectional view of FIG. 4 has only slight differences in the number and shape of the guard active fins 205 compared to the cross-sectional view of FIG. 3, the differences will be described.

Referring to FIG. 4, the guard active fin structure RX1 may include, for example, four active fins, and the four active fins may be a first active fin, a second active fin, a third active fin, and a fourth active fin in the order from the left, which is only exemplary. The number of active fins is not limited thereto and may vary according to embodiments. In an embodiment, the pair of guard contact structures CA1 may be respectively connected to, e.g., contact, the second active fin and the third active fin. In this case, the first interlayer insulating layer 181 may be arranged between the pair of guard contact structures CA1 and between the second and third active fins below the guard wiring structure CM1.

In any one of the plurality of guard active structures RX1, top surfaces of internal active fins 205a may respectively contact the guard contact structures CA1 and top surfaces of external active fins 205b may overlap the insulating material structures 110, 112, 114, 181, 182, 183, and 184 in the vertical direction. Here, the vertical direction may be a direction perpendicular to the top surface of the substrate 101, for example, the Z direction.

The guard active structure RX1 may include the external active fins 205b apart from each other, and the internal active fins 205a apart from each other between the external active fins 205b. In each of the guard active structures RX1, the top surfaces of some of the external and internal active fins 205b and 205a may overlap the insulating material structures 110, 112, 114, 181, 182, 183, and 184 in the vertical direction, and the top surfaces of the remaining external and internal active fins 205b and 205a may contact the guard contact structures CA1.

Among the external and internal active fins 205b and 205a, top surfaces of the active fins overlapping the insulating material structures 110, 112, 114, 181, 182, 183, and 184 in the vertical direction may be at a higher level than top surfaces of the active fins contacting the guard contact structures CA1.

A distance between adjacent internal active fins 205a may be less than a distance between adjacent external active fins 205b. However, the inventive concept is not limited thereto.

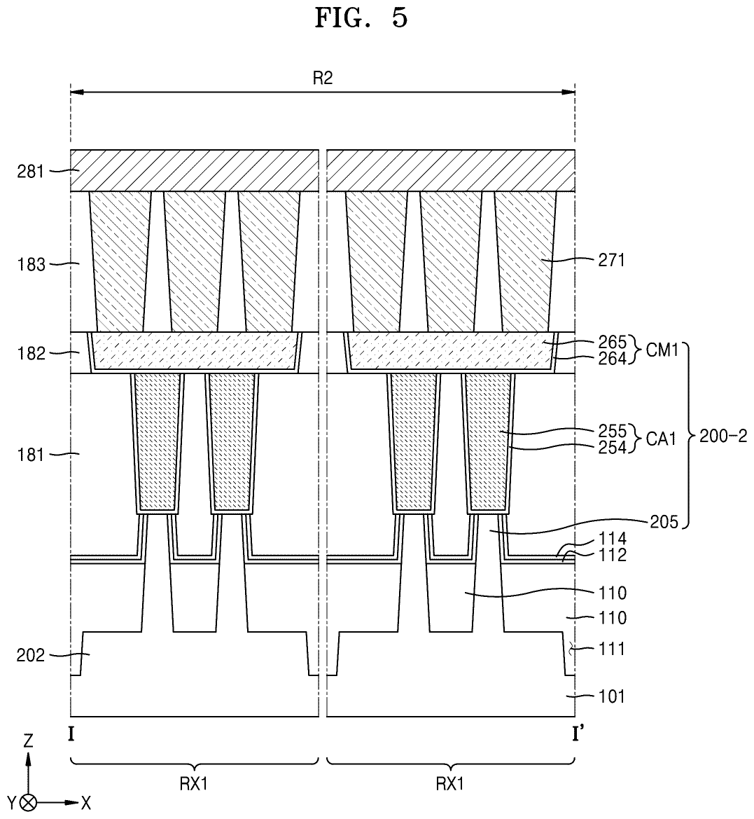

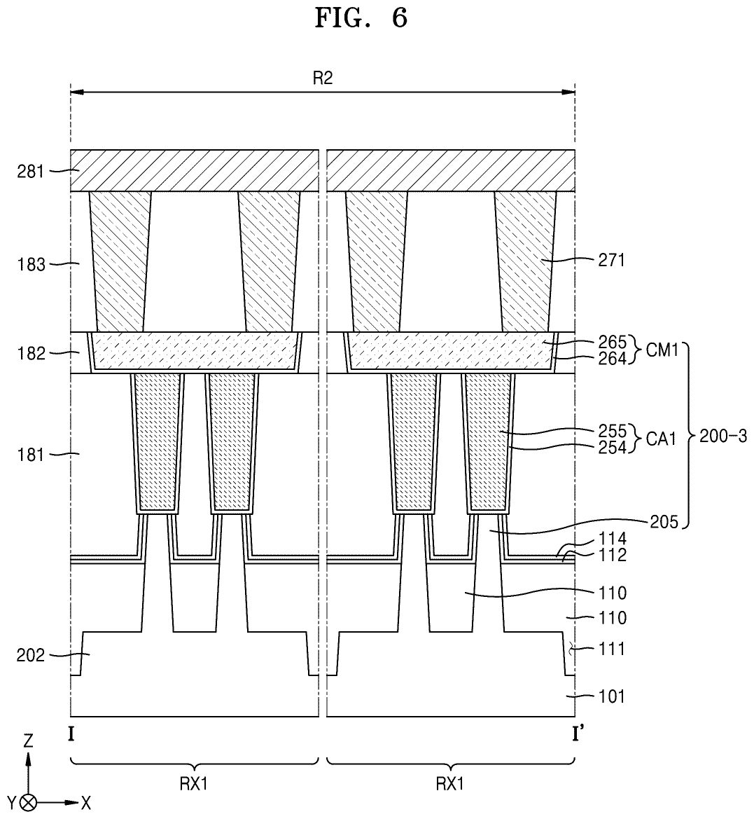

Although it is illustrated in the guard ring 200-1 of FIG. 4 that each of the vias 271 overlaps a corresponding one of the guard contact structures CA1 in the Z direction, the inventive concept is not limited thereto. As will be described later, referring to the guard rings 200-2 and 200-3 of FIGS. 5 and 6, a distance between adjacent vias 271 may be different from a distance between adjacent guard contact structures CA1.

FIG. 5 is a cross-sectional view illustrating a guard ring 200-2 region of a semiconductor device 10 according to embodiments. FIG. 5 may be a cross-sectional view of another embodiment taken along the line I-I′ of FIG. 2. In FIG. 5, the same reference numerals as in FIG. 3 denote the same members, and redundant description thereof will be omitted. Because the cross-sectional view of FIG. 5 has only slight differences in the number and arrangement of the vias 271 compared to the cross-sectional view of FIG. 3, the differences will be described.

Referring to FIG. 5, three vias 271 may be connected to one guard wiring structure CM1, which is only exemplary. In another embodiment, four or more vias 271 may be connected to one guard wiring structure CM1. In an embodiment, the number of guard contact structures CA1 and the number of vias 271 formed on one guard active structure RX1 may be different from each other. For example, the guard contact structures CA1 and the vias 271 may be formed so as not to overlap each other in the Z direction. For example, centers of the guard contact structures CA1 and centers of the vias 271 may not overlap each other in the Z direction. Therefore, a distance between the guard contact structures CA1 and a distance between the vias 271 on one guard active structure RX1 may be different from each other.

FIG. 6 is a cross-sectional view illustrating a guard ring 200-3 region of a semiconductor device 10 according to embodiments. FIG. 6 may be a cross-sectional view of another embodiment taken along the line I-I′ of FIG. 2. In FIG. 6, the same reference numerals as in FIG. 3 denote the same members, and redundant description thereof will be omitted. Because the cross-sectional view of FIG. 6 has only slight differences in the position of the vias 271 compared to the cross-sectional view of FIG. 3, the differences will be described.

Referring to FIG. 6, although the same number of guard contact structures CA1 and vias 271 are formed on one guard active structure RX1, a distance between adjacent guard contact structures CA1 may be different from a distance between adjacent vias 271. Although it is illustrated in FIG. 6 that a distance between adjacent vias 271 is greater than a distance between adjacent guard contact structures CA1, the distance between the adjacent vias 271 may be less than the distance between the adjacent guard contact structures CA1 in certain embodiments.

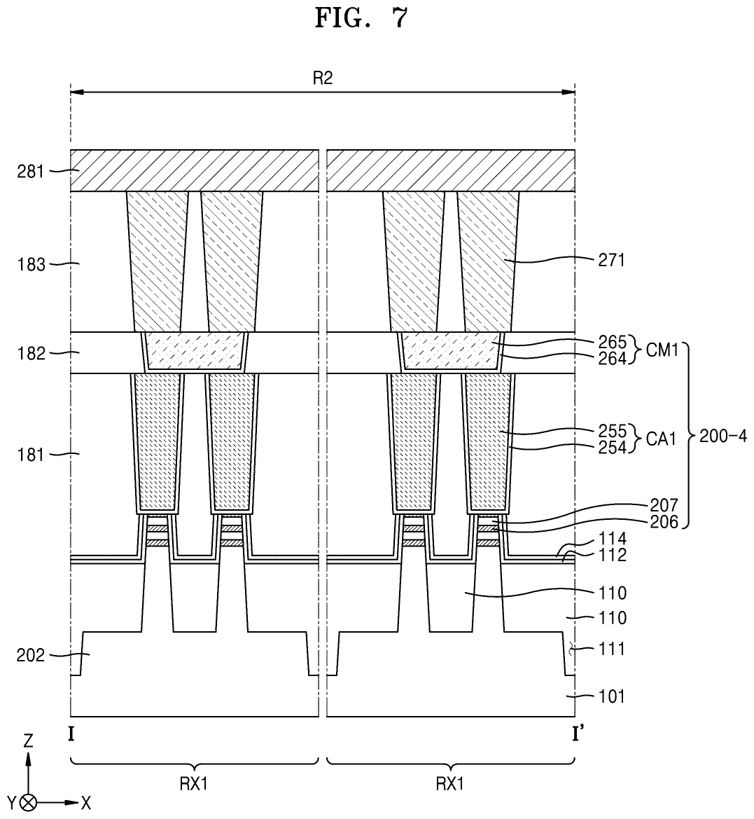

FIG. 7 is a cross-sectional view illustrating a guard ring 200-4 region of a semiconductor device 10 according to embodiments. FIG. 7 may be a cross-sectional view of another embodiment taken along the line I-I′ of FIG. 2. In FIG. 7, the same reference numerals as in FIG. 3 denote the same members, and redundant description thereof will be omitted. Because the cross-sectional view of FIG. 7 has only slight differences in the configuration of the guard active fins 205 compared to the cross-sectional view of FIG. 3, the differences will be described.

Referring to FIG. 7, the guard active fins 205 of the guard ring 200-4 may include a semiconductor stacked structure in which first semiconductor layers 206 and second semiconductor layers 207 are repeatedly/alternately stacked. The guard contact structure CA1 may contact the semiconductor stacked structure by partially recessing an upper portion of the semiconductor stacked structure. For example, the guard contact structure CA1 may be formed on the semiconductor stacked structure after removing a portion of the upper portion of the semiconductor stacked structure. For example, the first semiconductor layer 206 may include SiGe, and the second semiconductor layer 207 may include Si.

In the current embodiment, the first semiconductor layers 206 and the second semiconductor layers 207 may be manufactured in a process of forming a multi-bridge channel field effect transistor (MBCFET) of an integrated circuit structure 100a to be described later with reference to FIG. 9D. For example, the second semiconductor layers 207 may be formed in the same process as channel layers 121, 122, and 123 of FIG. 9D. The first semiconductor layers 206 may be formed in the same process as sacrificial layers replaced by gate electrodes 145a among the channel layers 121, 122, and 123 of FIG. 9D.

An integrated circuit structure of a semiconductor device according to an embodiment will be described with reference to FIGS. 8 to 9D. FIG. 8 is a partially enlarged view of the region ‘B’ of FIG. 1, FIG. 9A is a cross-sectional view taken along the line II-II′ of FIG. 8, FIG. 9B is a cross-sectional view taken along the line III-III′ of FIG. 8, and FIG. 9C is a cross-sectional view taken along the line IV-IV′ of FIG. 8.

Referring to FIGS. 8 to 9C, the integrated circuit structure 100 of the semiconductor device 10 may include the circuit active fins 105 on the substrate 101 of the first region R1, the device isolation region 110 defining the circuit active fins 105, the gate structure 140 extending across the circuit active fins 105, and the source/drain regions 130 on the circuit active fins 105 adjacent to side surfaces of the gate structure 140.

In the integrated circuit structure 100, the circuit active fins 105 may be parts of FinFETs, which are transistors in which channel regions of the transistors are formed in the circuit active fins 105 intersecting the gate structure 140. Description of the structure of the circuit active fins 105 the same as the structure of the guard active fins 205 will be omitted from the present disclosure, and the description with respect to the guard active fins 205 may be referenced for the circuit active fins 105. However, the circuit active fins 105 on the substrate 101 are partially recessed on both sides of the gate structure 140, and the source/drain regions 130 may be arranged on the recessed circuit active fins 105. For example, portions of the circuit active fins 105 on which the source/drain regions 130 are formed may have a lower height than other parts of the circuit active fins 105. According to embodiments, the circuit active fins 105 may include impurities, and at least some of the circuit active fins 105 may include impurities of different conductivity types. However, the inventive concept is not limited thereto.

The device isolation region 110 may define the circuit active fins 105 in the substrate 101. Descriptions of the structures of the device isolation region 110 and the circuit active fins 105 in the first region R1 which are the same as the structures of the device isolation region 110 and the guard active fins 205 in the second region R2 will be omitted from the present disclosure, and the descriptions with respect to the device isolation region 110 and the guard active fins 205 in the second region R2 may be referenced for device isolation region 110 and the circuit active fins 105 in the first region R1.

The source/drain regions 130 may be interposed between the circuit active fins 105 and the circuit contact structures CA. Each of the source/drain regions 130 may be provided as a source region or a drain region of a transistor. The source/drain regions 130 may be arranged by partially recessing upper portions of the circuit active fins 105. For example, the circuit active fins 105 on which the source/drain regions 130 are formed may be lower than other parts of the circuit active fins 105. However, whether or not there are recesses and a depth of the recesses may vary according to embodiments. The source/drain regions 130 may include a semiconductor layer including Si or an epitaxial layer. The source/drain regions 130 may include impurities of different types and/or different concentrations. For example, the source/drain regions 130 may include n-type doped Si and/or p-type doped SiGe. In embodiments, the source/drain regions 130 may include a plurality of regions including different concentrations of elements and/or doping elements.

The gate structure 140 may be arranged on the circuit active fins 105 to intersect the circuit active fins 105 and to extend longitudinally in a horizontal direction, for example, a Y direction. The channel regions of the transistors may be formed in the circuit active fins 105 intersecting the gate structure 140. For example, the channel regions of the transistors may be formed in the circuit active fins overlapping the gate structure 140, e.g., in a vertical direction and/or in a horizontal direction. The gate structure 140 may include a gate electrode 145, a gate dielectric layer 142 between the gate electrode 145 and the circuit active fins 105, a gate spacer layer 144 on side surfaces of the gate electrode 145, and a gate capping layer 146 on the gate electrode 145.

The gate dielectric layer 142 may be arranged between the circuit active fins 105 and the gate electrode 145. The gate dielectric layer 142 may be arranged to surround all surfaces of the gate electrode 145 except for the uppermost surface. The gate dielectric layer 142 may include oxide, nitride, or a high-k material.

The gate electrode 145 may be arranged on the circuit active fins 105 to intersect the circuit active fins 105. The gate electrode 145 may include a conductive material, for example, a metal nitride layer such as a titanium nitride layer (TiN), a tantalum nitride layer (TaN), or a tungsten nitride layer (WN), and/or a metal material such as aluminum (Al), tungsten (W), or molybdenum (Mo), or a semiconductor material such as doped polysilicon. The gate electrode 145 may include two or more multi-layers.

The gate spacer layers 144 may be arranged on both side surfaces of the gate electrode 145 and may extend in the Z direction perpendicular to the top surface of the substrate 101. The gate spacer layer 144 may have a multi-layer structure according to certain embodiments. The gate spacer layer 144 may be formed of oxide, nitride, and/or oxynitride, and particularly, may be formed of a low dielectric constant layer.

The gate capping layer 146 may be arranged on the gate electrode 145. The gate capping layer 146 may be arranged to extend along a top surface of the gate electrode 145 in a second direction, for example, the Y direction. The gate capping layer 146 may include oxide, nitride, or oxynitride.

The integrated circuit structure 100 of the semiconductor device 10 according to the current embodiment may include the first interlayer insulating layer 181 on the substrate 101, the circuit contact structures CA arranged on the source/drain regions 130 through the first interlayer insulating layer 181, a gate contact structure CB electrically connected to the gate electrode 145 through the first interlayer insulating layer 181, the second interlayer insulating layer 182 on the first interlayer insulating layer 181, a circuit wiring structure CM1a electrically connected to (e.g., contacting) a circuit contact structure CA through the second interlayer insulating layer 182, and a gate wiring structure CM1b arranged on (e.g., contacting) the gate contact structure CB through the second interlayer insulating layer 182.

The circuit contact structures CA may be electrically connected to the source/drain regions 130 through the first interlayer insulating layer 181 and may apply an electrical signal to the source/drain regions 130. The circuit contact structures CA may be arranged on the source/drain regions 130 as illustrated in FIG. 8 and, according to embodiments, may be arranged to have a longer length in the Y direction than the source/drain regions 130. The circuit contact structure CA may have an inclined side surface in which a width of a lower portion of the circuit contact structure CA is less than a width of an upper portion of the circuit contact structure CA in a horizontal direction (e.g., Y direction). For example, when a contact hole for a circuit contact structure CA is formed in the first interlayer insulating layer 181, a lower part of the contact hole may have a width less than a width of an upper part of the contact hole according to an aspect ratio of the contact hole. However, the inventive concept is not limited thereto. In embodiments, the circuit contact structures CA may recess upper portions of the source/drain regions 130. For example, the circuit contact structures CA may be formed on recesses formed in upper portions of the source/drain regions 130. In embodiments, the circuit contact structures CA may be arranged to contact the top surfaces of the source/drain regions 130 without recessing the source/drain regions 130. For example, the circuit contact structures CA may contact flat top surfaces of the source/drain regions 130 in certain embodiments.

The circuit contact structure CA may include a metal-semiconductor compound layer 152a, a barrier layer 154a, and a contact plug 155a. The barrier layer 154a may surround the contact plug 155a. The barrier layer 154a may cover/contact side and bottom surfaces of the contact plug 155a. The metal-semiconductor compound layer 152a may be arranged between the barrier layer 154a and a corresponding source/drain region 130.

The metal-semiconductor compound layer 152a may include a metal silicide layer, a metal germanide layer, or a metal silicide-germanide layer. Here, the metal may include or may be Ti, nickel (Ni), tantalum (Ta), Co, or W, and the semiconductor may include or may be Si, Ge, or SiGe. The barrier layer 154a may include a metal nitride layer such as a titanium nitride layer (TiN), a tantalum nitride layer (TaN), or a tungsten nitride layer (WN). The contact plug 155a may include, for example, W, Co, Ti, an alloy thereof, or a combination thereof.

The gate contact structure CB may be electrically connected to the gate electrode 145 through the first interlayer insulating layer 181 and the gate capping layer 146 and may apply an electrical signal to the gate electrode 145. The gate contact structure CB may be arranged on the gate electrode 145 as illustrated in FIG. 9C. The gate contact structure CB may have an inclined side surface in which a width of a lower portion of the gate contact structure CB is less than a width of an upper portion of the gate contact structure CB in a horizontal direction (e.g., Y direction). For example, when a gate contact hole for the gate contact structure CB is formed in the first interlayer insulating layer 181 and the gate capping layer 146, a lower part of the gate contact hole may have a width less than a width of an upper part of the gate contact hole according to an aspect ratio of the gate contact hole. However, the inventive concept is not limited thereto. In embodiments, the circuit contact structures CA may recess upper portions of the source/drain regions 130. For example, the circuit contact structures CA may be formed on recesses formed in upper portions of the source/drain regions 130.

The gate contact structure CB may include a gate barrier layer 154b and a gate contact plug 155b. The gate barrier layer 154b may surround the gate contact plug 155b. The gate barrier layer 154b may cover/contact side and bottom surfaces of the gate contact plug 155b.

The gate barrier layer 154b may include a metal nitride layer such as a titanium nitride layer (TiN), a tantalum nitride layer (TaN), or a tungsten nitride layer (WN). The gate contact plug 155b may include, for example, W, Co, Ti, an alloy thereof, or a combination thereof.

In embodiments, a bottom surface of the gate contact plug 155b may be higher than a bottom surface of the contact plug 155a. A top surface of the gate contact plug 155b may be substantially coplanar with a top surface of the first interlayer insulating layer 181 and/or a top surface of the contact plug 155a. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

The circuit wiring structure CM1a may be electrically connected to (e.g., contact) the circuit contact structure CA through the second interlayer insulating layer 182. The circuit wiring structure CM1a may have an inclined side surface in which a width of a lower portion of the circuit wiring structure CM1a is less than a width of an upper portion of the circuit wiring structure CM1a in a horizontal direction (e.g., Y direction). For example, when the second interlayer insulating layer 182 is patterned to form the circuit wiring structure CM1a in the second interlayer insulating layer 182, an upper part of the second interlayer insulating layer 182 may be more widely etched than a lower part of the second interlayer insulating layer 182 according to an aspect ratio of the etching portion. However, the inventive concept is not limited thereto.

The circuit wiring structure CM1a may include a metal barrier layer 164a and a metal wiring layer 165a. The metal barrier layer 164a may surround the metal wiring layer 165a. The metal barrier layer 164a may cover/contact side and bottom surfaces of the metal wiring layer 165a.

The metal barrier layer 164a may include a metal nitride layer such as a titanium nitride layer (TiN), a tantalum nitride layer (TaN), or a tungsten nitride layer (WN). The metal wiring layer 165a may include, for example, W, Co, Ti, an alloy thereof, or a combination thereof.

The gate wiring structure CM1b may be electrically connected to the gate contact structure CB through the second interlayer insulating layer 182. The gate wiring structure CM1b may have an inclined side surface in which a width of a lower portion of the gate wiring structure CM1b is less than a width of an upper portion of the gate wiring structure CM1b in a horizontal direction (e.g., Y direction). For example, when the second interlayer insulating layer 182 is patterned to form the gate wiring structure CM1b in the second interlayer insulating layer 182, an upper part of the second interlayer insulating layer 182 may be more widely etched than a lower part of the second interlayer insulating layer 182 according to an aspect ratio of the etching portion. However, the inventive concept is not limited thereto.

The gate wiring structure CM1b may include a gate conductive barrier layer 164b and a gate conductive wiring layer 165b. The gate conductive barrier layer 164b may surround the gate conductive wiring layer 165b. The gate conductive barrier layer 164b may cover/contact side and bottom surfaces of the gate conductive wiring layer 165b.

The gate conductive barrier layer 164b may include a metal nitride layer such as a titanium nitride layer (TiN), a tantalum nitride layer (TaN), or a tungsten nitride layer (WN). The gate conductive wiring layer 165b may include, for example, W, Co, Ti, an alloy thereof, or a combination thereof.

The integrated circuit structure 100 of the semiconductor device 10 according to the current embodiment may further include a body contact structure applying a body bias to the substrate 101 in the first region R1. The body contact structure may contact at least parts of the circuit active fins 105.

The integrated circuit structure 100 of the semiconductor device 10 according to the current embodiment may include a third interlayer insulating layer 183 on the second interlayer insulating layer 182, first and second circuit region vias 171 and 172 respectively electrically connected to the circuit contact structure CA and the gate contact structure CB through the third interlayer insulating layer 183, a fourth interlayer insulating layer 184 on the third interlayer insulating layer 183, and the first and second circuit region conductive lines 191 and 192 respectively electrically connected to the first and second circuit region vias 171 and 172 through the fourth interlayer insulating layer 184.

The first to fourth interlayer insulating layers 181, 182, 183, and 184 may be sequentially stacked on the substrate 101. At least one of the first to fourth interlayer insulating layers 181, 182, 183, 184 may include, for example, tetraethyl ortho silicate (TEOS), undoped silicate glass (USG), phosphosilicate glass (PSG), borosilicate glass (BSG), borophosphosilicate glass (BPSG), fluoride silicate glass (FSG), spin on glass (SOG), tonensilazene (TOSZ), or a combination thereof.

The first and second circuit region vias 171 and 172 may respectively contact a top surface of the metal wiring layer 165a and a top surface of the gate metal wiring layer 165b through the third interlayer insulating layer 183. The first and second circuit region vias 171 and 172 may include copper (Cu) or a copper-containing alloy.

The first and second circuit region conductive lines 191 and 192 may respectively contact a top surface of the first circuit region via 171 and a top surface of the second circuit region via 172 through the fourth interlayer insulating layer 184. The first and second circuit region conductive lines 191 and 192 may include Cu or a copper-containing alloy.

FIG. 9D is a cross-sectional view illustrating a semiconductor device according to embodiments. FIG. 9D is a cross-sectional view of the semiconductor device of FIG. 8 taken along the line II-II′.

Referring to FIG. 9D, the integrated circuit structure 100a of the semiconductor device 10 may further include a channel structure 120 including the plurality of channel layers 121, 122, and 123 arranged on the circuit active fins 105 to be vertically apart from one another. The gate electrode 145a may be arranged between the circuit active fins 105 and the channel structure 120, between the plurality of channel layers 121, 122, and 123 of the channel structure 120, and above the channel structure 120. Accordingly, the integrated circuit structure 100a may include the MBCFET including the channel structure 120, the source/drain regions 130, and a gate structure 140a.

In the integrated circuit structure 100a of the semiconductor device 10, the gate structure 140a may further include internal spacer layers 141. The internal spacer layers 141 may be arranged parallel to the gate electrode 145a between the channel structures 120. The internal spacer layers 141 may be arranged on both sides of the gate structure 140a in the X direction on bottom surfaces of the first to third channel layers 121, 122, and 123. The internal spacer layers 141 may have external surfaces substantially coplanar with external surfaces of the first to third channel layers 121, 122, and 123. Under the third channel layer 123, the gate electrode 145a may be electrically separated/insulated from the source/drain regions 130 by the internal spacer layers 141. The internal spacer layers 141 may include oxide, nitride, or oxynitride, and particularly, may include a low dielectric constant layer.

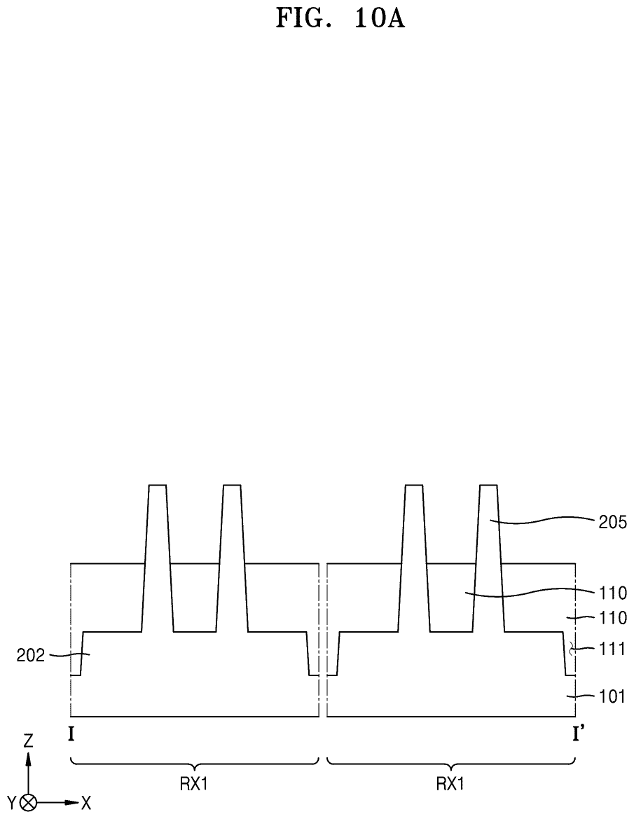

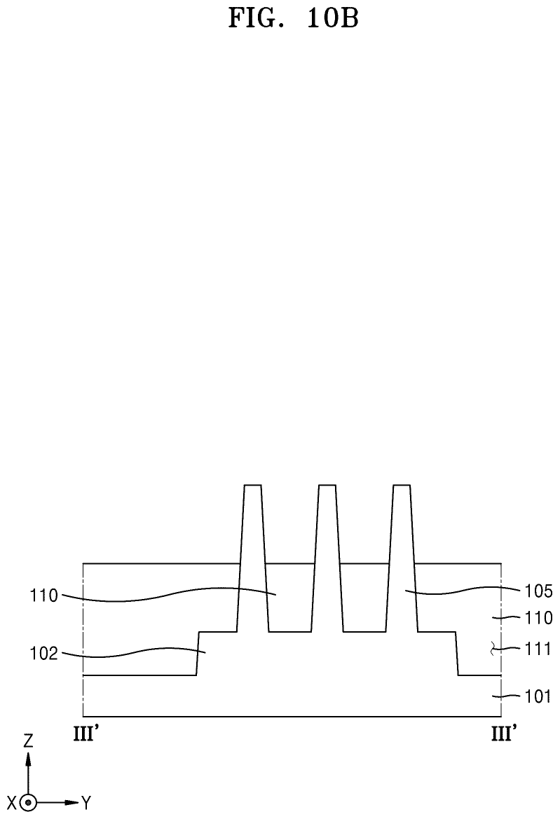

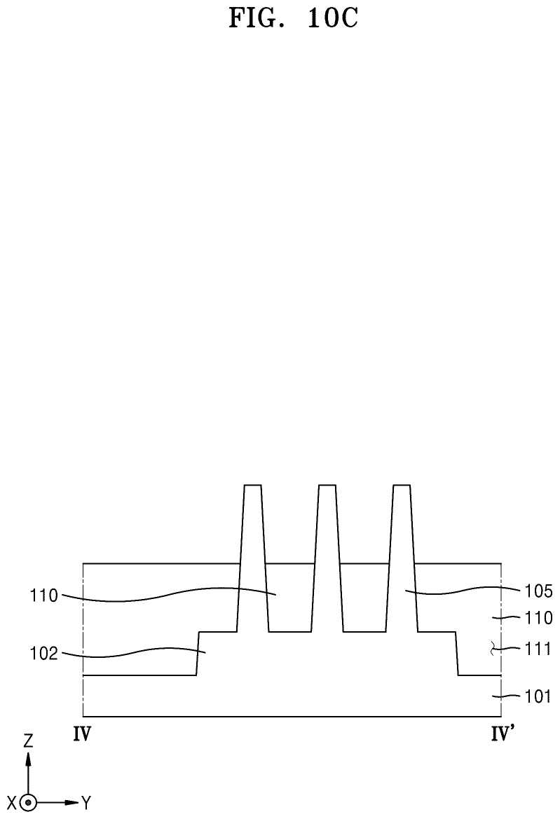

FIGS. 10A to 16C are views illustrating a method of manufacturing a semiconductor device according to embodiments in a process order. In FIGS. 10A to 16C, an embodiment of a method of manufacturing the semiconductor device of FIGS. 2 to 3 will be described.

Referring to FIGS. 10A, 10B, and 10C, a plurality of active fins may be formed on the substrate 101.

The active fins 105 may be defined by the device isolation region 110 in the first region R1 of the substrate 101. The guard active fins 205 may be defined by the device isolation region 110 in the second region R2 of the substrate 101. The active fins 105 and the guard active fins 205 may protrude from the substrate 101.

In another embodiment, a plurality of sacrificial layers and the channel layers 121, 122, and 123 may be alternately stacked on the substrate 101. The sacrificial layers may be replaced by the gate dielectric layer 142 and the gate electrode 145 through a subsequent process as illustrated in FIG. 9D. The sacrificial layers may include a material having etch selectivity with respect to the channel layers 121, 122, and 123. For example, the sacrificial layers may be removed in a subsequent etching process while the channel layers 121, 122, and 123 are not substantially etched. For example, the sacrificial layers may include SiGe, and the channel layers 121, 122, and 123 may include Si.

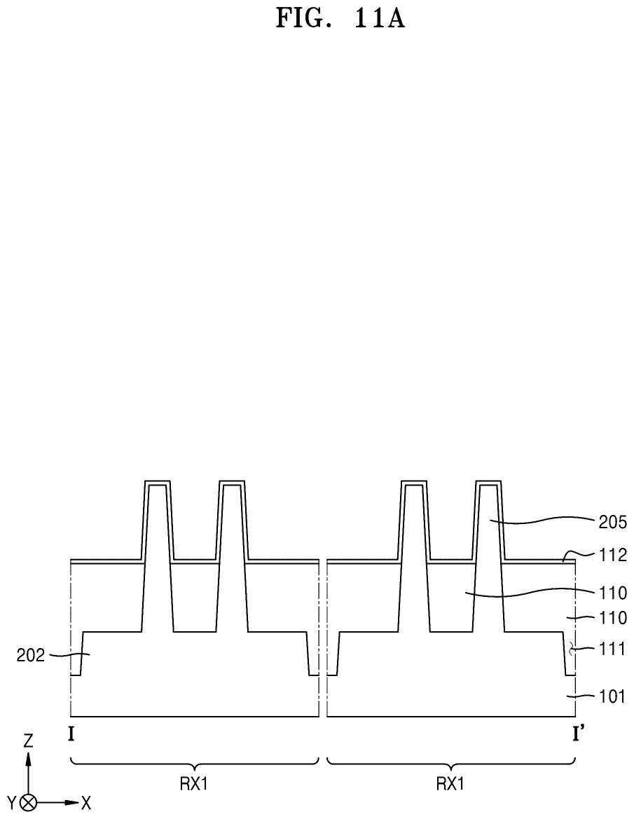

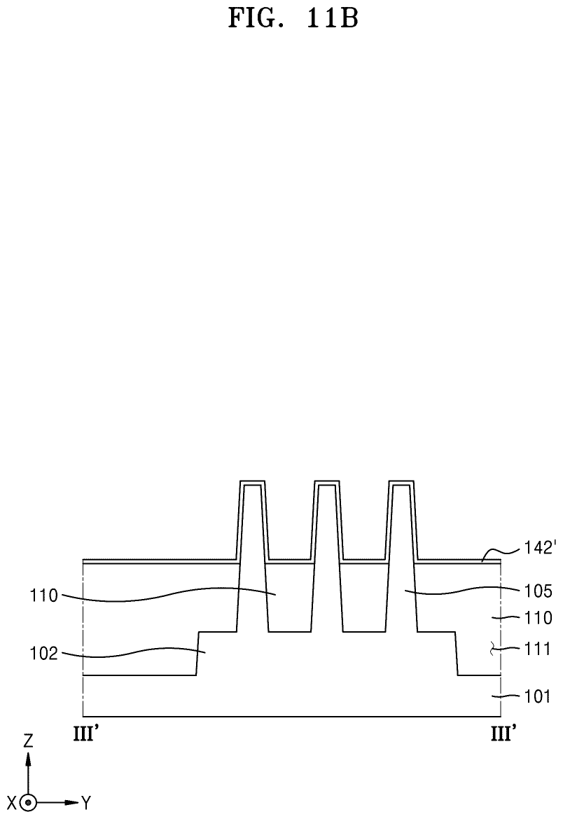

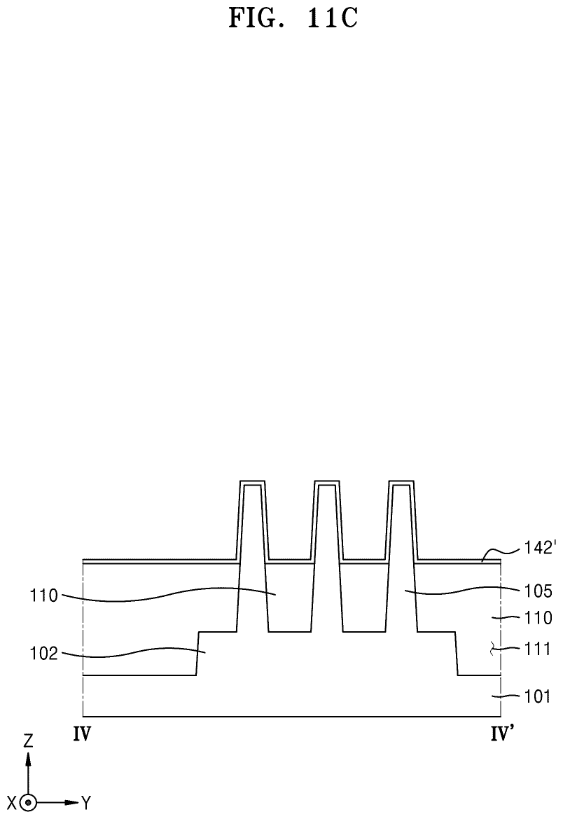

Referring to FIGS. 11A, 11B, and 11C, the first protective layer 112 covering the active fins 105, the guard active fins 205, and the device isolation region 110 may be formed.

The first protective layer 112 may conformally cover the active fins 105 and the guard active fins 205. The first protective layer 112 may be formed over the first and second regions R1 and R2 of the substrate 101, or may be formed only in a partial region, for example, the second region R2. For example, the first protective layer 112 formed in the first region R1 may be patterned by a gate electrode mask pattern layer 146′ in a process to be described later to remain as a sacrificial gate dielectric layer 142′. The first protective layer 112 may include, for example, oxide, nitride, or a combination thereof.

The first protective layer 112 may protect the guard active fins 205 of the second region R2 in a process of forming the source/drain regions 130 and the gate structure 140 to be described later.

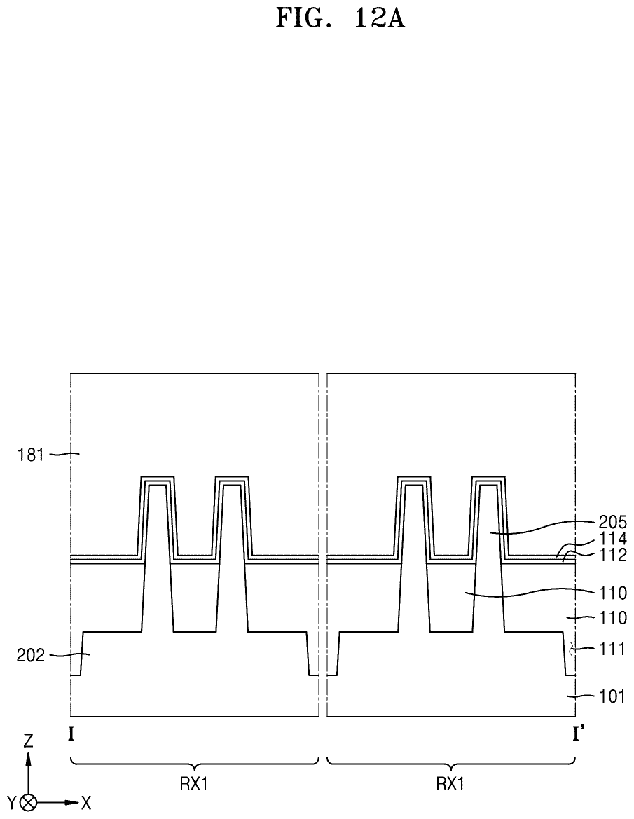

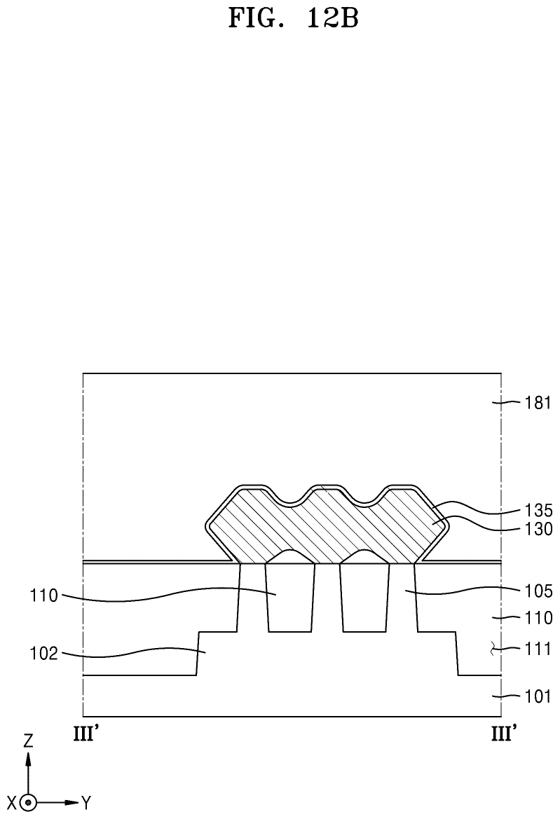

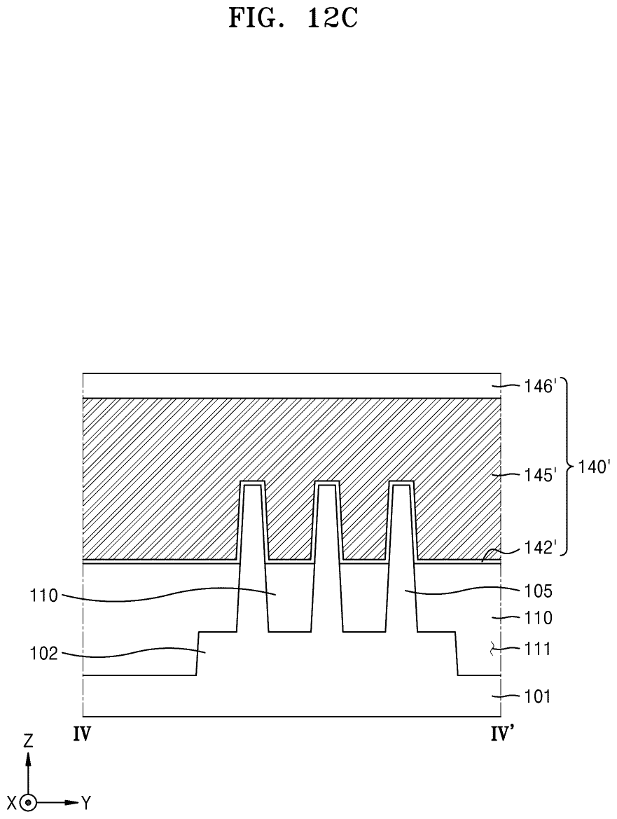

Referring to FIGS. 12A, 12B, and 12C, sacrificial gate structures 140′ may be formed across the active fins 105. Parts of the active fins 105 may be removed and a selective epitaxial growth (SEG) process may be performed to form the source/drain regions 130 on the active fins 105. The etch stop layer 135 may be formed to cover the source/drain regions 130. The first interlayer insulating layer 181 may be formed between the sacrificial gate structure 140′ and on the source/drain regions 130.

First, the sacrificial gate structures 140′ extending lengthwise in a horizontal direction (Y direction) across the active fins 105 may be formed in the first region R1. The sacrificial gate structure 140′ may include the sacrificial gate dielectric layer 142′, a sacrificial gate electrode 145′, and the gate electrode mask pattern layer 146′. The sacrificial gate dielectric layer 142′ and the sacrificial gate electrode 145′ may be patterned by using the gate electrode mask pattern layer 146′. The sacrificial gate dielectric layer 142′ may include silicon oxide, and the sacrificial gate electrode 145′ may include polysilicon. The gate electrode mask pattern layer 146′ may include silicon oxide and/or silicon nitride. The sacrificial gate structures 140′ may have a line shape, e.g., in a plan view, for example, may extend straight in the Y direction and may be apart from each other in the X direction.

The gate spacer layer 144 (refer to FIG. 9A) may be formed on both sidewalls of the sacrificial gate structure 140′. The gate spacer layer 144 may be formed by forming a layer of a uniform thickness along top and side surfaces of the sacrificial gate structure 140′ and then anisotropically etching the layer.

Next, parts of the active fins 105 may be removed from both sides of the sacrificial gate structure 140′ and a selective epitaxial growth process may be performed on the removed active fins 105 to form the source/drain regions 130. Recesses may be formed by removing parts of the active fins 105. The recesses may be formed by forming a separate mask layer or etching parts of the active fins 105 by using the gate electrode mask pattern layer 146′ and the gate spacer layer 144 as masks. For example, the recesses may be formed by sequentially applying a dry etching process and a wet etching process. The source/drain regions 130 may be formed on the etched active fins 105. The source/drain regions 130 may include impurities formed by in-situ doping and may include a plurality of layers having different doping elements and/or doping concentrations.

Next, after forming the etch stop layer 135 to cover the source/drain regions 130, the first interlayer insulating layer 181 may be formed.

The etch stop layer 135 may cover the source/drain regions 130 and the device isolation region 110 in the first region R1. The etch stop layer 135 may cover side surfaces of the gate spacer layer 144. The etch stop layer 135 may also be formed in the second region R2 and may be the second protective layer 114 in the second region R2. For example, the second protective layer 114 of the second region R2 and the etch stop layer 135 in the first region R1 may be formed by the same deposition process with the same material. The second protective layer 114 may cover the first protective layer 112 in the second region R2.

The first interlayer insulating layer 181 may be formed to cover the etch stop layer 135 between the sacrificial gate structures 140′ of the first region R1. The first interlayer insulating layer 181 may be formed to cover the second protective layer 114 of the second region R2. The first interlayer insulating layer 181 may be formed by forming an insulating layer covering the sacrificial gate structures 140′ and the source/drain regions 130 and performing a planarization process.

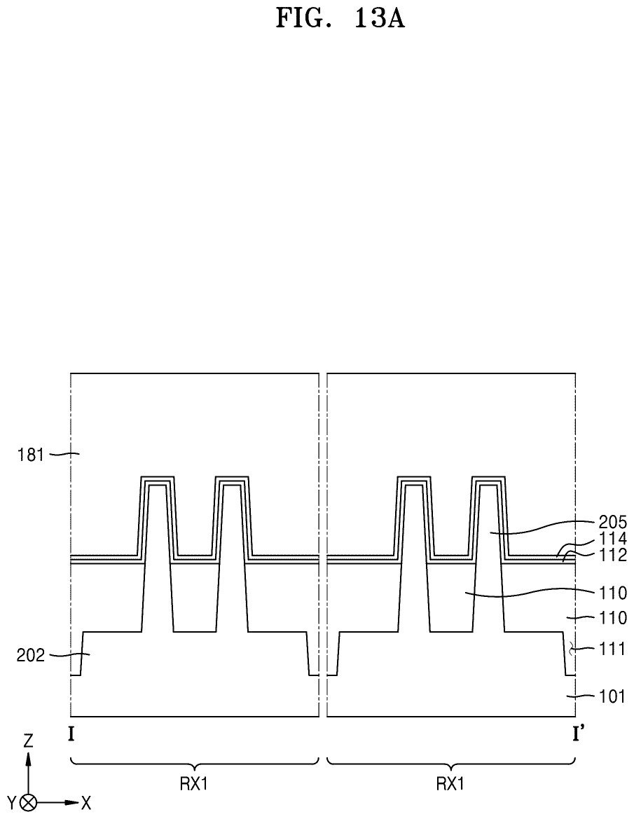

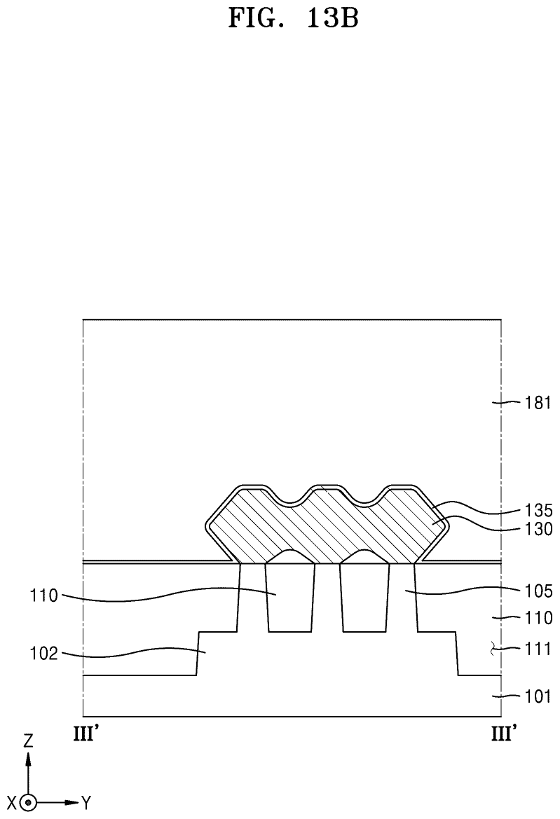

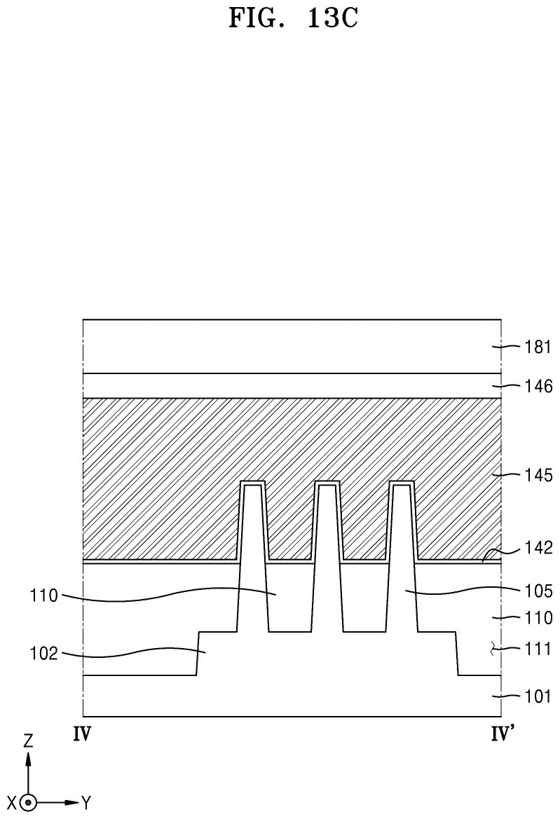

Referring to FIGS. 13A, 13B, and 13C, gap regions may be formed by removing the sacrificial gate structure 140′, and the gate dielectric layer 142, the gate electrode 145, and the gate capping layer 146 may be formed in the gap regions.

The sacrificial gate structure 140′ may be selectively removed with respect to the gate spacer layer 144, the first interlayer insulating layer 181, and the active fins 105. The gap regions may be formed by removing the sacrificial gate structure 140′.

The gate dielectric layer 142 and the gate electrode 145 may be formed to fill the gap regions and then may be removed from tops of the gap regions to a predetermined depth. The gate capping layer 146 may be formed in a region, from which the gate electrode 145 is removed, in the gap regions. Accordingly, the gate structure 140 including the gate dielectric layer 142, the gate electrode 145, the gate spacer layer 144, and the gate capping layer 146 may be formed.

Referring to FIGS. 14A, 14B, and 14C, the first interlayer insulating layer 181 may be patterned to form guard contact holes GH1 and contact holes CH1.

The contact holes CH1 may be formed by partially removing the first interlayer insulating layer 181 from both sides of the gate structure 140 by using a separate mask layer such as a photoresist pattern. Bottom surfaces of the contact holes CH1 may be recessed into the source/drain regions 130 or may be curved along top surfaces of the source/drain regions 130. In embodiments, a shape and arrangement of the contact holes CH1 may vary.

The guard contact holes GH1 may be formed by partially removing the first interlayer insulating layer 181 by using a separate mask layer such as a photoresist pattern. The guard contact holes GH1 may partially recess the guard active fins 205 (e.g., by removing a portion of the first protective layer 112, a portion of the second protective layer 114, and/or a portion of the guard active fins 205) to expose the guard active fins 205. The guard contact holes GH1 may also partially expose the first and second protective layers 112 and 114. At least two guard contact holes GH1 may be formed per guard active structure RX1.

The guard contact holes GH1 are formed as a pair, and insulating residue generated in a process of patterning and partially removing the first interlayer insulating layer 181 may be prevented from being deposited in the guard contact holes GH1. For example, according to some embodiments of the present disclosure, a pair of narrow guard contact holes GH1 may be formed instead of a wide guard contact hole in the first interlayer insulating layer 181 in the second region R2, and a guard contact structure CA1 may fill up the pair of narrow guard contact holes GH1 when the guard contact structure CA1 is deposited in the guard contact holes GH1. Therefore, the present embodiment is beneficial to prevent insulating residue from being attached in a space formed in the guard contact structure CA1 which may be formed when the guard contact hole is wide and the guard contact structure CA1 does not fully fill up the guard contact hole but a space remains within the guard contact hole GH1.

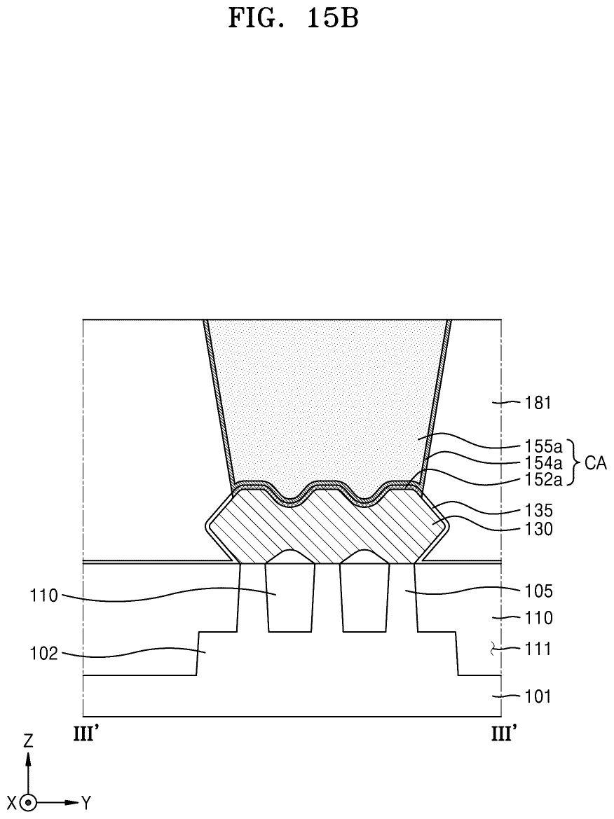

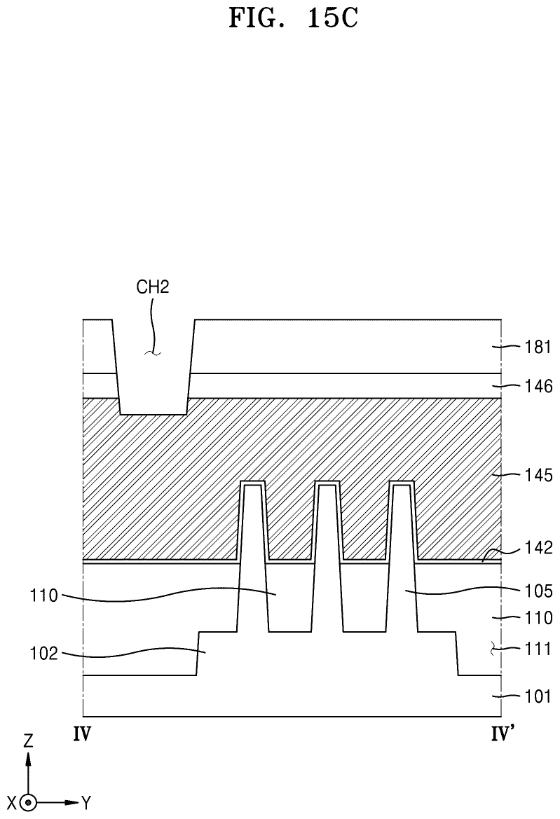

Referring to FIGS. 15A, 15B, and 15C, the circuit contact structures CA and the guard contact structures CA1 may be formed. The first interlayer insulating layer 181 may be patterned to form gate contact holes CH2.

The circuit contact structures CA may respectively be formed in the contact holes CH1. The metal-semiconductor compound layer 152a may be formed on surfaces of the source/drain regions 130 exposed by the contact holes CH1. The barrier layers 154a and the contact plugs 155a may be sequentially formed in the contact holes CH1.

The guard contact structures CA1 may be respectively formed in the guard contact holes GH1. The guard barrier layers 254 and the guard contact plugs 255 may be sequentially formed in the guard contact holes GH1.

A planarization process may be performed in the process of forming the guard contact structures CA1 and the circuit contact structures CA to flatten top surfaces of the guard contact structures CA1 and the circuit contact structures CA at the same level of a top surface of the first interlayer insulating layer 181.

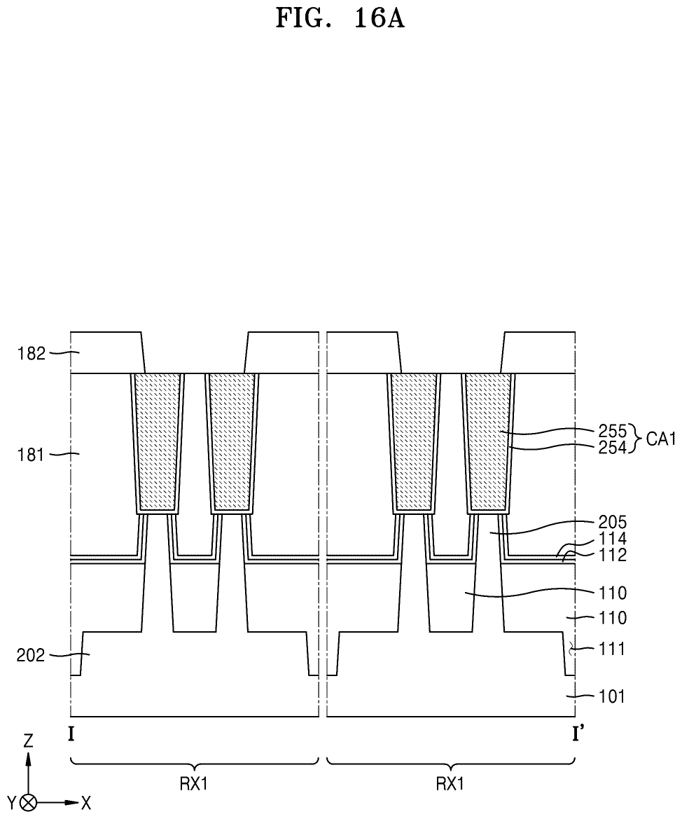

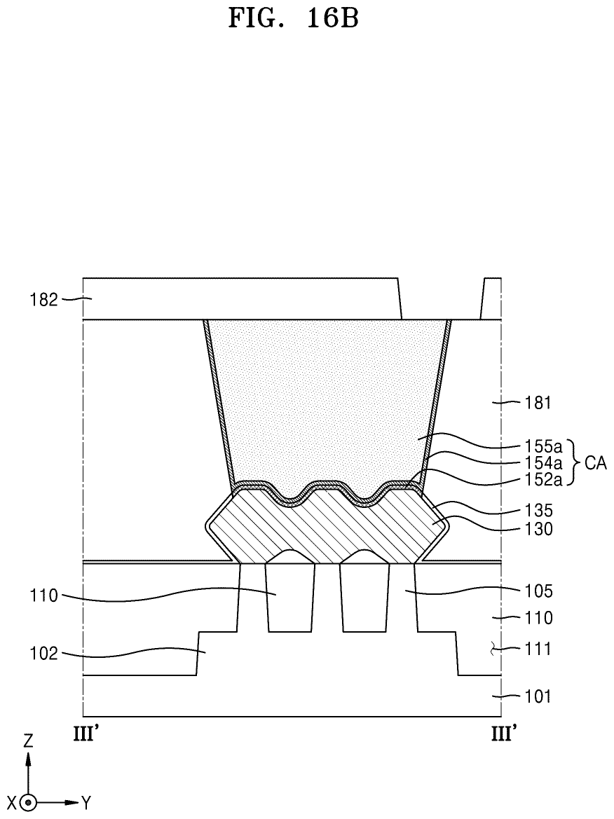

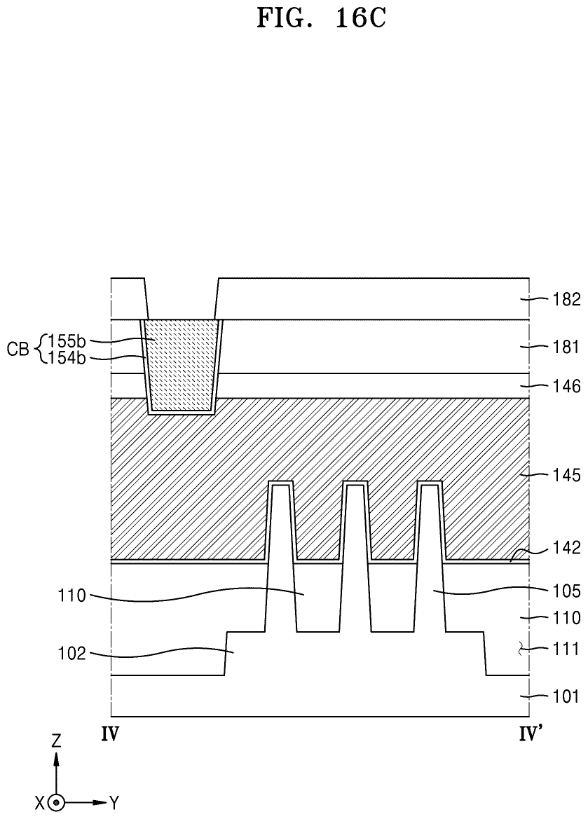

Referring to FIGS. 16A, 16B, and 16C, the gate contact structures CB may be formed in the gate contact holes CH2. The second interlayer insulating layer 182 may be formed on the first interlayer insulating layer 181 and the second interlayer insulating layer 182 may be partially removed to form a wiring trench.

Referring to FIGS. 3, 4, and 9A to 9C together, wiring layers may be formed in the wiring trench, the third interlayer insulating layer 183 and the plurality of vias 171, 172, and 271 may be formed, and the conductive lines 191, 192, and 281 may be formed on the third interlayer insulating layer 183.

The semiconductor device 10 according to embodiments of the inventive concept may include the guard rings 200, 200-1, 200-2, 200-3, and 200-4 in which two or more guard contact structures CA1 are arranged on each guard active structure RX1. A width of each of the guard contact structures CA1 may be less than or equal to a width of the first circuit region via 171, and the sum of widths of the plurality of guard contact structures CA1 may be greater than a width of the circuit contact structure CA. Unfilled space of the structure of the guard rings 200, 200-1, 200-2, 200-3, and 200-4 may be prevented to reduce the possibility of particle contamination due to voids that may occur in a guard ring pattern and to improve reliability of the device. In addition, the guard contact structure CA1 and the via 271 may be arranged to vertically overlap each other, e.g., at the same position in a plan view (refer to FIGS. 3, 4, and 7) or may be arranged at positions that do not vertically overlap each other or partially overlap each other in a vertical direction (refer to FIGS. 5 and 6), thereby securing a degree of freedom in a design of a guard ring structure. In addition, the number of guard contact structures CA1 and the number of vias 271 may be the same (refer to FIGS. 3, 4, 6, and 7) or different from each other (refer to FIG. 5).

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

What is claimed is:

1. A semiconductor device comprising:
a substrate having a first region and a second region surrounding the first region;
an integrated circuit structure on the substrate in the first region;
a guard ring surrounding the integrated circuit structure on the substrate in the second region;
a plurality of vias arranged on the guard ring; and
a conductive line arranged on the plurality of vias,
wherein the integrated circuit structure comprises a circuit active fin on the substrate in the first region, a gate structure intersecting the circuit active fin, a source/drain region on an active fin adjacent to a side surface of the gate structure, a circuit contact structure on the source/drain region, and a circuit wiring structure on the circuit contact structure,
wherein the guard ring comprises a guard active structure on the substrate in the second region, a plurality of guard contact structures arranged on the guard active structure, and a guard wiring structure on the guard contact structures, and
wherein the guard contact structures overlap the plurality of vias in a vertical direction perpendicular to a top surface of the substrate.

2. The semiconductor device of claim 1, wherein the plurality of vias contacts the guard wiring structure.

3. The semiconductor device of claim 1, wherein a width of a topmost surface of each of the guard contact structures is equal to or less than a width of a topmost surface of the circuit contact structure.

4. The semiconductor device of claim 1, wherein a sum of widths of topmost surfaces of the guard contact structures is greater than a width of a topmost surface of the circuit contact structure.

5. The semiconductor device of claim 1, wherein a width of a vertical cross-section of each of the guard contact structures decreases in a direction receding downwards from a topmost surface of the guard contact structure.

6. The semiconductor device of claim 1, wherein the number of guard contact structures is the same as the number of vias.

7. The semiconductor device of claim 1, wherein the guard wiring structure contacts a top surface of each of the guard contact structures.

8. The semiconductor device of claim 1, further comprising an external guard ring formed on the substrate to surround an external surface of the guard ring.

9. The semiconductor device of claim 1, wherein the source/drain region is between the circuit contact structure and the circuit active fin.

10. The semiconductor device of claim 1, further comprising an insulating material structure on a side surface of the guard ring, wherein the insulating material structure comprises a device isolation region on side surfaces of the guard active structure and a protective layer covering the guard active structure on the device isolation region, and
wherein each of the guard contact structures contacts the protective layer.

11. A semiconductor device comprising:
a substrate;
an integrated circuit structure arranged on the substrate;
a guard ring arranged on the substrate to surround the integrated circuit structure at a position adjacent to an edge of the substrate;
a plurality of vias arranged on the guard ring; and
a conductive line connected to the plurality of vias,
wherein the integrated circuit structure comprises a circuit active fin on the substrate, a gate structure intersecting the circuit active fin, a source/drain region on a circuit active fin adjacent to a side surface of the gate structure, a circuit contact structure on the source/drain region, and a circuit wiring structure on the circuit contact structure,
wherein the guard ring comprises a guard active structure on the substrate, a plurality of guard contact structures arranged on the guard active structure, and a guard wiring structure on the guard contact structures, and
wherein the plurality of vias are arranged at positions that do not overlap the guard contact structures in a vertical direction.

12. The semiconductor device of claim 11, wherein the number of vias is different from the number of guard contact structures.

13. The semiconductor device of claim 11, wherein a distance between the guard contact structures is different from a distance between the vias.

14. The semiconductor device of claim 11, wherein a width of a topmost surface of each of the guard contact structures is equal to or less than a width of a topmost surface of the circuit contact structure.

15. The semiconductor device of claim 11, wherein a sum of widths of topmost surfaces of the guard contact structures is greater than a width of a topmost surface of the circuit contact structure.

16. The semiconductor device of claim 11, wherein a width of a vertical cross-section of each of the guard contact structures decreases in a direction receding downwards from a topmost surface of the guard contact structure.

17. A semiconductor device comprising:
an integrated circuit structure on a substrate;
a guard ring surrounding the integrated circuit structure on the substrate;
a conductive line at a vertical level higher than the guard ring;
a plurality of vias between a guard wiring structure and the conductive line; and
an insulating material structure on a side surface of the guard ring,
wherein the integrated circuit structure comprises a circuit active fin on the substrate, a gate structure intersecting the circuit active fin, a source/drain region on a circuit active fin adjacent to a side surface of the gate structure, a circuit contact structure on the source/drain region, and a circuit wiring structure on the circuit contact structure,
wherein the guard ring comprises a guard active structure on the substrate, guard contact structures arranged on the guard active structure to be apart from one another, and the guard wiring structure on the guard contact structures,
wherein the source/drain region is between the circuit contact structure and the circuit active fin,
wherein a width of a topmost surface of each of the guard contact structures is equal to or less than a width of a topmost surface of the circuit contact structure,
wherein a bottom surface of the guard wiring structure contacts a top surface of each of the guard contact structures, and
wherein a top surface of the guard wiring structure contacts bottom surfaces of the plurality of vias.

18. The semiconductor device of claim 17, wherein a sum of widths of topmost surfaces of the guard contact structures is greater than a width of a topmost surface of the circuit contact structure.

19. The semiconductor device of claim 17, wherein the plurality of vias are arranged at positions that do not overlap the guard contact structures in a vertical direction.

20. The semiconductor device of claim 17, wherein the plurality of vias are formed at positions overlapping the guard contact structures in a vertical direction.
